(19) United States
(12) Patent Application Publication
(10) Pub. No.: US 2026/0344395 A1
(43) Pub. Date: Oct. 29, 2026

(54) Substrate, Manufacturing Method Thereof, and Sensor Module

(71) Applicants: Beijing BOE Optoelectronics Technology Co., Ltd., Beijing (CN); BOE Technology Group Co., Ltd., Beijing (CN); Beijing BOE Technology Development Co., Ltd., Beijing (CN)

(72) Inventors: Hanqing LIU, Beijing (CN); Yifeng QIN, Beijing (CN); Lihui WANG, Beijing (CN); Pengcheng TIAN, Beijing (CN); Junru MA, Beijing (CN); Hongwen GUO, Beijing (CN); Haowei ZOU, Beijing (CN); Meijiao SONG, Beijing (CN); Shangxuan REN, Beijing (CN); Wei CHEN, Beijing (CN); Jun GUO, Beijing (CN); Xu LIU, Beijing (CN); Xin LI, Beijing (CN); Yue LI, Beijing (CN)

(21) Appl. No.: 18/995,985

(22) PCT Filed: Dec. 25, 2023
(86) PCT No.: PCT/CN2023/141565

§ 371 Date: Jan. 17, 2025

(51) Int. Cl. H10W 20/42; H10D 48/50; H10W 20/00; H10W 20/41; H10W 20/46; H10W 72/90

(52) U.S. Cl. CPC H10W 20/42; H10D 48/50; H10W 20/0595; H10W 20/067; H10W 20/438; H10W 20/46; H10W 72/9226

(57) ABSTRACT

A substrate, a manufacturing method thereof, and a sensor module. The substrate includes a base substrate (21) configured to be connected with a chip (10), and the base substrate is provided with a plurality of through-holes (100) penetrating the base substrate (21) in a direction perpendicular to the chip (10). Stacked structures are provided sequentially within the through-holes (100) in a direction perpendicular to and away from the base substrate (21), and thermal expansion coefficients of each layer in the stacked structures are different. The stacked structures include a first conductive portion (241) electrically connected to the chip (10).

### CROSS-REFERENCE TO RELATED APPLICATION

The present application is a U.S. National Phase Entry of International Application No. PCT/CN2023/141565 having an international filing date of Dec. 25, 2023, contents of which are incorporated into the present application by reference.

### TECHNICAL FIELD

The present application relates to, but is not limited to the field of integration technology, and in particular to a substrate, a manufacturing method thereof, and a sensor module.

### BACKGROUND

In recent years, with the vigorous rise of emerging fields such as 5G, wearable devices, smartphones, automotive electronics, and artificial intelligence, integrated circuit applications are developing in the direction of diversified applications, and advanced three-dimensional packaging technology has gradually become an important means to realize miniaturization, lightweight and multifunction of electronic products. Through-Hole Interconnection Technology has the application advantages such as excellent high-frequency electrical characteristics, low cost, simple process flow, and strong mechanical stability. It has a wide range of application prospects in the fields of radio frequency devices, micro-electromechanical systems (MEMS) packaging, and optoelectronic system integration and so on. Compared with the conventional planar integration technology, the through-hole interconnection technology can realize vertical interconnection, thus expanding the integrated space to the third dimension and significantly improving the utilization rate of space.

### SUMMARY

The following is a summary of the subject matter described in detail in the present application. This summary is not intended to limit the protection scope of claims.

In one aspect, the present application provides a substrate, including a base substrate configured to be connected with a chip. The base substrate is provided with a plurality of through-holes which penetrate the base substrate in a direction perpendicular to the chip, stacked structures are sequentially provided within the through-holes in a direction perpendicular to and away from the base substrate, and thermal expansion coefficients of each layer in the stacked structures are different.

The stacked structures include a first conductive portion electrically connected to the chip.

In the other aspect, the present application also provides a sensor module, including: the substrate as described above; and a chip, which is electrically connected to a surface of the base substrate close to the chip.

In another aspect, the present application further provides a manufacturing method of a substrate, including: providing a base substrate connected to a chip; forming a plurality of through-holes on the base substrate, the through-holes penetrating the base substrate in a direction perpendicular to the chip; and forming stacked structures sequentially in the through-holes in a direction perpendicular to and away from the base substrate. Thermal expansion coefficients of each layer in the stacked structures are different, and the stacked structures include a first conductive portion electrically connected to the chip.

Other aspects of the present disclosure may be comprehended after the drawings and the detailed description are read and understood.

### BRIEF DESCRIPTION OF DRAWINGS

Accompanying drawings are used for providing an understanding of technical solutions of the present application and form a part of the specification, are used for explaining the technical solutions of the present application together with embodiments of the present application, and do not constitute a limitation on the technical solutions of the present application.

FIGS. 1A and 1B are schematic views of a sensor module after forming a base substrate pattern in an embodiment of the present application;

FIGS. 2A and 2B are schematic views of a sensor module after forming a first conductive layer in an embodiment of the present application;

FIGS. 3A and 3B are schematic views of a sensor module after forming a second conductive layer in an embodiment of the present application;

FIGS. 4A and 4B are schematic views of a sensor module after forming a conductive structure pattern in an embodiment of the present application;

FIGS. 5A and 5B are schematic views of a sensor module after forming an insulation layer pattern in an embodiment of the present application;

FIGS. 6A and 6B are schematic views of a sensor module after forming a connection electrode pattern in an embodiment of the present application;

FIGS. 7A and 7B are schematic views of a sensor module after forming a base substrate pattern in another embodiment of the present application;

FIGS. 8A and 8B are schematic views of a sensor module after forming a buffer layer in another embodiment of the present application;

FIGS. 9A and 9B are schematic views of a sensor module after forming a first conductive layer pattern in another embodiment of the present application;

FIGS. 10A and 10B are schematic views of a sensor module after forming a second conductive layer in another embodiment of the present application;

FIGS. 11A and 11B are schematic views of a sensor module after forming a conductive structure pattern in another embodiment of the present application;

FIGS. 12A and 12B are schematic views of a sensor module after forming an insulation layer pattern in another embodiment of the present application;

FIGS. 13A and 13B are schematic views of a sensor module after forming a connection electrode pattern in another embodiment of the present application;

FIGS. 14A and 14B are schematic views of a sensor module after forming a base substrate pattern in yet another embodiment of the present application;

FIGS. 15A and 15B are schematic views of a sensor module after forming a first conductive layer pattern in yet another embodiment of the present application, wherein grooves are located in through-holes;

FIGS. 16A and 16B are schematic views of a sensor module after forming a second conductive layer pattern in yet another embodiment of the present application;

FIGS. 17A and 17B are schematic views of a sensor module after forming a conductive structure pattern in yet another embodiment of the present application;

FIGS. 18A and 18B are schematic views of a sensor module after forming an insulation layer pattern in yet another embodiment of the present application;

FIGS. 19A and 19B are schematic views of a sensor module after forming a connection electrode pattern in yet another embodiment of the present application;

FIGS. 20A, 20B, and 20C are partial schematic views of a sensor module after forming a first conductive layer pattern in yet another embodiment of the present application;

FIGS. 20D and 20E are schematic views of a sensor module after forming a first conductive layer pattern in yet another embodiment of the present application, wherein grooves are located around through-holes;

FIG. 20F is a schematic cross-sectional view of a sensor module after forming a first conductive layer pattern in yet another embodiment of the present application, wherein some of grooves are sequentially provided in a direction perpendicular to the chip;

FIGS. 21A and 21B are schematic views of a sensor module after forming a base substrate pattern in a further embodiment of the present application;

FIGS. 22A and 22B are schematic views of a sensor module after forming the first conductive layer in a further embodiment of the present application;

FIGS. 23A and 23B are schematic views of a sensor module after forming a filling structure layer in a further embodiment of the present application;

FIGS. 24A and 24B are schematic views of a sensor module after forming a conductive structure pattern in a further embodiment of the present application;

FIGS. 25A and 25B are schematic views of a sensor module after forming an insulation layer pattern in a further embodiment of the present application; and

FIGS. 26A and 26B are schematic views of a sensor module after forming a connection electrode pattern in a further embodiment of the present application.

### DESCRIPTION OF REFERENCE SIGNS

10—Chip; 11—Electrode part; 12—Piezoresistor; 20—Substrate; 21—Base substrate; 22—First conductive layer; 23—Second conductive layer; 24—Conductive structure; 241—First conductive portion; 242—Second conductive portion; 243—Buffer part; 25—Insulation layer; 26—Connection electrodes; 27—Buffer layer; 28—Filler; 100—Through-hole; 200—Slot structure; 300—Chamber; 400—Via; 500—Connection hole; 600—Groove; 700—Cavity.

### DETAILED DESCRIPTION

In order to make purposes, technical solutions and advantages of the present application clearer, embodiments of the present application will be described in detail below with reference to the accompanying drawings. It is to be noted that implementations may be implemented in multiple different forms. Those of ordinary skills in the art may easily understand such a fact that modes and contents may be transformed into various forms without departing from the purpose and scope of the present application. Therefore, the present application should not be construed as only being limited to the contents recorded in the following implementations. The embodiments in the present application and features in the embodiments can be combined with each other arbitrarily if there is no conflict.

Scales of the drawings in the present application may be used as a reference in actual processes, but are not limited thereto. For example, a width-length ratio of a channel, a thickness and spacing of each film layer, and a width and spacing of each signal line may be adjusted according to actual needs. A quantity of pixels in a display substrate and a quantity of sub-pixels in each pixel are not limited to numbers shown in the drawings. The drawings described in the present application are schematic structural views only, and one mode of the present application is not limited to shapes, numerical values, or the like shown in the drawings.

Ordinal numerals “first”, “second”, “third”, etc., in the specification are set not to form limits in numbers but only to avoid confusion between constituent elements.

In the specification, for convenience, expressions “central”, “above”, “below”, “front”, “back”, “vertical”, “horizontal”, “top”, “bottom”, “inside”, “outside”, etc., for indicating directional or positional relationships are used to illustrate positional relationships between the constituent elements with reference to the drawings, not to indicate or imply that involved devices or elements are required to have specific orientations or are structured and operated in the specific orientations but only to easily describe the present specification and simplify the description, and thus should not be understood as limitations on the present application. The positional relationships between the constituent elements may be changed as appropriate based on a direction according to which each constituent element is described. Therefore, appropriate replacements based on situations are allowed, and the positional relationships are not limited to the expressions in the specification.

In the specification, unless otherwise explicitly specified and defined, terms “mounting”, “coupling”, and “connection” should be understood in a broad sense. For example, a connection may be a fixed connection, or a detachable connection, or an integral connection; it may be a mechanical connection or an electrical connection; it may be a direct connection, or an indirect connection through a middleware, or an internal communication between two elements. For those of ordinary skills in the art, specific meanings of the above terms in the present application may be understood according to specific situations.

In the specification, a transistor refers to an element that at least includes three terminals, i.e., a gate electrode, a drain electrode, and a source electrode. The transistor has a channel region between the drain electrode (drain electrode terminal, drain region, or drain) and the source electrode (source electrode terminal, source region, or source), and a current can flow through the drain electrode, the channel region, and the source electrode. It is to be noted that in the specification, the channel region refers to a region through which a current mainly flows.

In the specification, a first electrode may be a drain electrode, and a second electrode may be a source electrode. Alternatively, the first electrode may be a source electrode, and the second electrode may be a drain electrode. In a case that transistors with opposite polarities are used, or in a case that a direction of a current changes during operation of a circuit, or the like, functions of the “source electrode” and the “drain electrode” are sometimes interchangeable. Therefore, the “source electrode” and the “drain electrode”, as well as the “source terminal” and the “drain terminal”, are interchangeable in the specification.

In the specification, “electrical connection” includes connection of constituent elements through an element with a certain electrical action. An “element with a certain electrical action” is not particularly limited as long as electrical signals may be sent and received between the connected constituent elements. Examples of the “element with a certain electrical action” not only include an electrode and a wiring, but also include a switching element such as a transistor, a resistor, an inductor, a capacitor, another element with various functions, etc.

In the specification, “parallel” refers to a state in which an angle formed by two straight lines is −10° or more and 10° or less, and thus also includes a state in which the angle is −5° or more and 5° or less. In addition, “perpendicular” refers to a state in which an angle formed by two straight lines is 80° or more and 100° or less, and thus also includes a state in which the angle is 85° or more and 95° or less.

In the specification, a “film” and a “layer” are interchangeable. For example, a “conductive layer” may be replaced with a “conductive film” sometimes. Similarly, an “insulation film” may be replaced with an “insulation layer” sometimes.

Triangle, rectangle, trapezoid, pentagon, hexagon and the like in this specification are not strictly defined, and they may be approximate triangle, rectangle, trapezoid, pentagon, hexagon and the like. There may be some small deformations caused by tolerance, and there may be chamfer, arc edge, deformation, etc.

In the present application, “about” refers to that a boundary is defined not so strictly and numerical values within process and measurement error ranges are allowed.

At present, one of the technical difficulties limiting the application of through-hole interconnection technology is high-quality metal filling. Different from the through silicon vias (TSV), through-holes with larger diameters require long electroplating time and high cost. On the other hand, unlike silicon materials, base substrates with smooth surfaces (for example, glass base substrates) have poor adhesion to common metals (such as, Cu), which is likely to cause delamination between the base substrate and the metal layer, resulting in the metal layer curls or even falls off.

In the actual process of electroplating hole filling, it is found that when electroplating and filling a through-hole with a diameter of 50-300 μm and a depth of about 300 μm, if the electroplating working current is set too high, the metal at the top of the through-hole grows too fast, resulting in the through-hole being quickly sealed, while the metal at the bottom of the through-hole is not fully filled, and the purpose of hole electrical interconnection cannot be realized. At the same time, if the through-hole is not fully filled, it will also affect the subsequent coating effect of the film layer, and produce more defects. In the subsequent exposure process of the through-hole structure, due to the large diameter and unfilled condition, the photoresist will accumulate in the through-hole, resulting in thin or missing photoresist at the edges, and resulting in failure of the electrical connection of the hole.

When aiming to realize full hole filling, the significant difference between the thermal expansion coefficient of common metals (such as Cu) and the thermal expansion coefficient of the base substrate can lead to the concentration of substantial stress at the through-hole position during the subsequent high-temperature process (such as annealing and reflow soldering). This can result in cracks or direct breakage at the through-hole position.

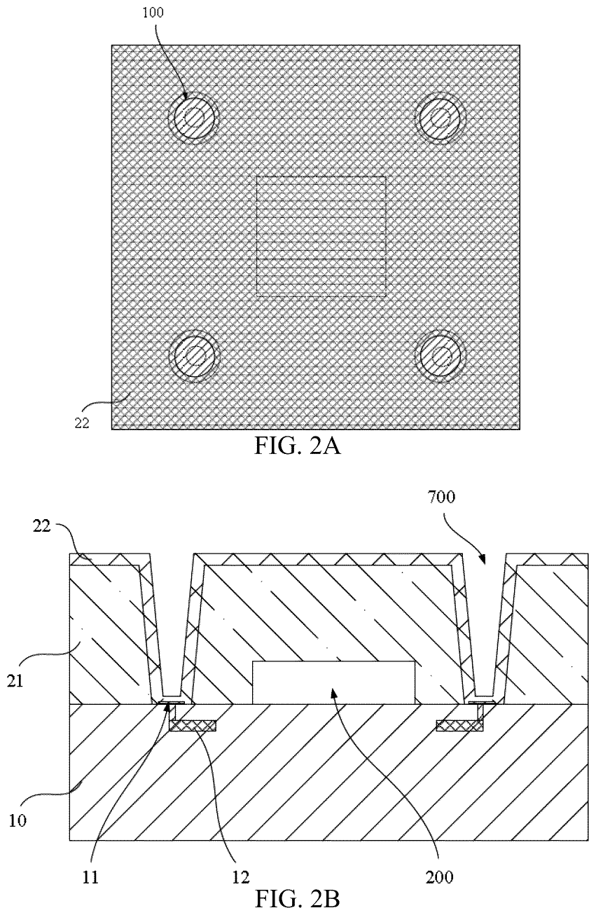

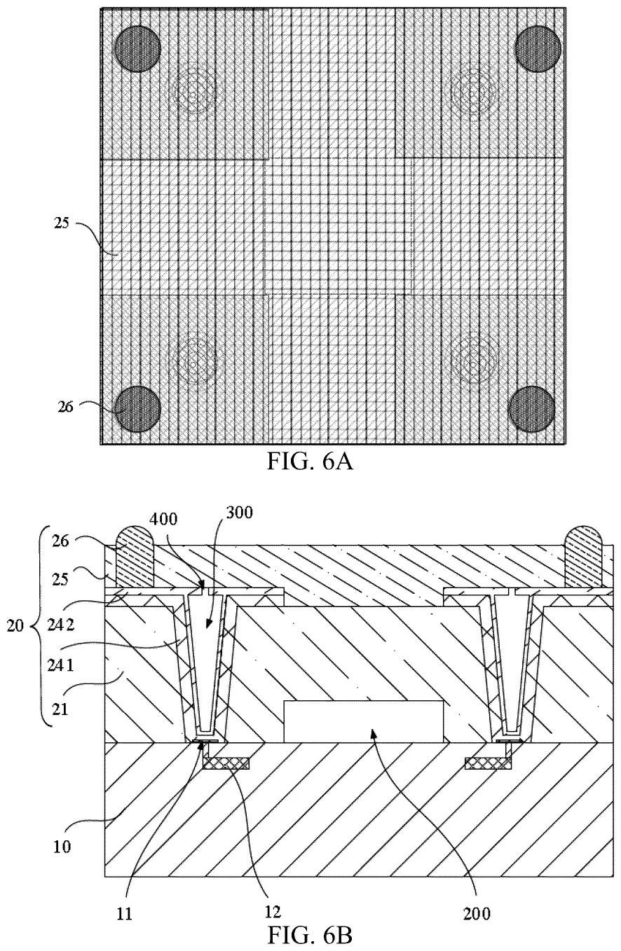

FIG. 2A is a schematic planar view of a sensor module after forming a first conductive layer in an embodiment of the present application. FIG. 2B is a schematic cross-sectional view of the sensor module after forming the first conductive layer in an embodiment of the present application. FIG. 6A is a schematic planar view of a sensor module after forming a connection electrode pattern in an embodiment of the present application. FIG. 6B is a schematic cross-sectional view of the sensor module after forming the connection electrode pattern in an embodiment of the present application, wherein the cross-section is perpendicular to a chip 10.

In a plane perpendicular to the chip 10, a substrate 20 includes a base substrate 21. The base substrate 21 is configured to be connected to the chip 10, and the base substrate 21 is provided with a plurality of through-holes 100 penetrating the base substrate 21 in a direction perpendicular to the chip. Stacked structures are sequentially provided within the through-holes 100 in a direction perpendicular to and away from the base substrate 21. The stacked structures include a first conductive portion 241 electrically connected to the chip 10 to ensure electrical conductivity of the first conductive portion 241 within the through-holes 100. Objects expand or contract due to temperature changes. Their ability to change is expressed by the change of length value caused by the change of unit temperature under equal pressure (constant pressure), that is, a thermal expansion coefficient. Thermal expansion coefficients of each layer in the stacked structures are different. In this way, the stress of each layer can be released towards adjacent layers with relatively small thermal expansion coefficients, thereby avoiding the easy concentration of larger stresses at the through-holes 100 during subsequent high-temperature manufacturing processes (such as annealing and reflow soldering), which could cause cracks or direct breakage of the through-holes 100.

In an exemplary embodiment, the stacked structures further include a cavity 700 provided on a side of the first conductive portion 241 away from the chip 10. The cavity 700 is a chamber filled with gas and has a low thermal expansion coefficient.

As a result, the through-holes 100 are in an unfilled state, which ensures the electrical conductivity of the first conductive portion 241 in the through-holes 100 and realizes electrical connection. At the same time, the through-holes 100 are in an unfilled state so that the first conductive portion 241 is spatially conducive to stress release, and cracks or even breakage at the positions of the through-holes 100 due to excessive stress of the first conductive portion 241 are avoided. The stacked structures may include the first conductive portion 241 and the cavity 700.

In an exemplary embodiment, the substrate 20 further includes a second conductive portion 242. The second conductive portion 242 is provided on a side of the first conductive portion 241 away from the chip 10 and closes a side of a through-hole away from the chip 10, such that the side of the through-hole 100 away from the chip 10 is flat. In this way, the photoresist can be homogenized normally by spin coating, spraying, etc., and the thickness of the photoresist at the through-hole 100 is normal, such that the photoresist can be prevented from accumulating in the through-hole 100. This accumulation could lead to the loss or thinness of the photoresist at the side of the through-hole 100 away from the chip 10 and cause partial etching of the first conductive portion 241 at the side of the through-hole 100 away from the chip 10 during etching, resulting in abnormal electrical conduction at the position of the through-hole 100. The first conductive portion 241 and the second conductive portion 242 jointly enclose a chamber 300.

In an exemplary embodiment, the second conductive portion 242 is provided with a via 400. The via 400 penetrates the second conductive portion 242 in a direction perpendicular to the chip 10, and communicates with the chamber 300, so as to prevent the electroplating solution from remaining in the chamber 300 after the through-holes 100 are closed, which could lead to bad reliability.

In an exemplary implementation, a diameter of the via 400 may be about 10 μm to 20 μm. Setting the diameter of the via 400 to a smaller size can prevent the second conductive part 242 from being collapsed by force and affecting the electrical conduction.

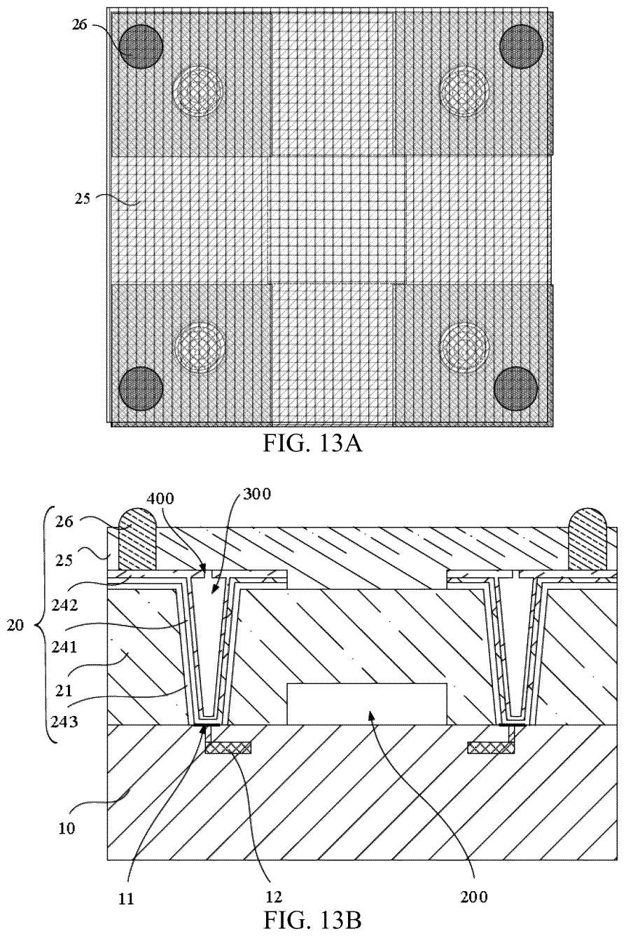

In an exemplary implementation, FIG. 13A is a schematic view of a planar structure of a sensor module after forming a connection electrode pattern in another embodiment of the present application. FIG. 13B is a schematic view of a cross-sectional structure of the sensor module after forming the connection electrode pattern in another embodiment of the present application, wherein the cross-section is perpendicular to the chip 10.

The stacked structures further include a buffer layer 243 provided on a side of the base substrate 21 away from the chip 10, and the first conductive portion 241 is provided on a side of the buffer layer 243 away from the chip 10. At this time, the stacked structures may include the first conductive portion 241, the cavity 700, and/or the buffer layer 243.

A thermal expansion coefficient of a material of the buffer layer 243 is between a thermal expansion coefficient of a material of the base substrate and a thermal expansion coefficient of a material of the first conductive portion. By providing the buffer layer 243, the stress gradient between the base substrate 21 and the first conductive portion 241 can be reduced, and the risk of delamination between the base substrate 21 and the first conductive portion 241 can be reduced. In an embodiment of the present application, the base substrate 21 is a glass base substrate, and the thermal expansion coefficient of the material of the buffer layer 243 is between the thermal expansion coefficient of the glass and the thermal expansion coefficient of the material of the first conductive portion 241.

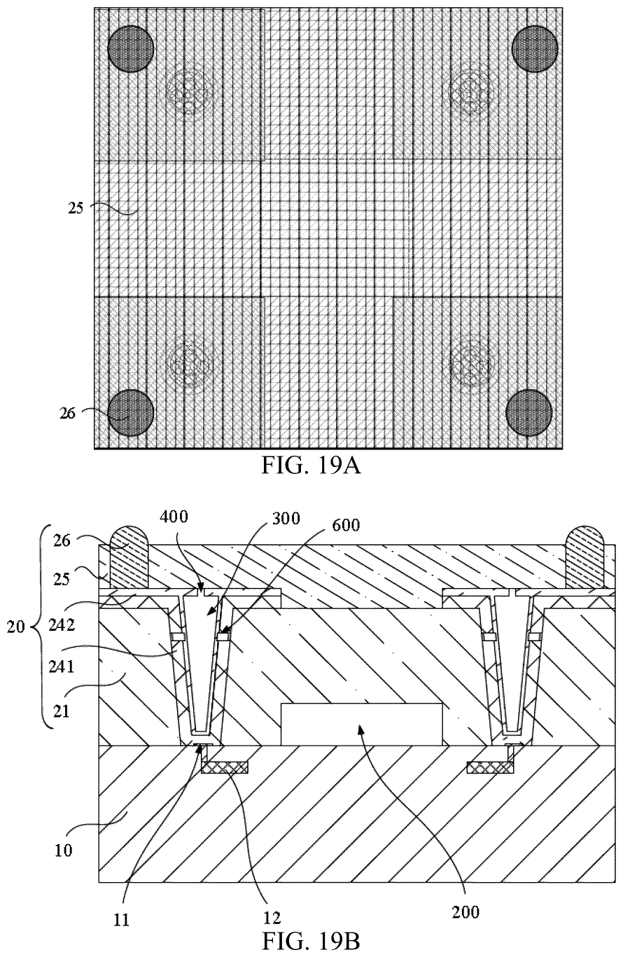

In an exemplary implementation, FIG. 19A is a schematic view of a planar structure of a sensor module after forming a connection electrode pattern in yet another embodiment of the present application. FIG. 19B is a schematic view of a cross-sectional structure of the sensor module after forming the connection electrode pattern in yet another embodiment of the present application, wherein the cross-section is perpendicular to the chip 10.

The first conductive portion 241 is provided with a groove 600. The arrangement of the groove 600 does not affect the electrical conductivity characteristics of the first conductive portion 241. With the arrangement of the groove 600, when the stress of the first conductive portion 241 increases during the subsequent manufacturing process, the stress of the first conductive portion 241 can be first released at the groove 600, resulting in partial delamination and warping and other phenomenon around the groove 600, thereby reducing the influence on the adhesion and electrical conductivity characteristics of the overall film layer of the first conductive portion 241.

In an exemplary implementation, at least one groove 600 is provided within the through-hole 100.

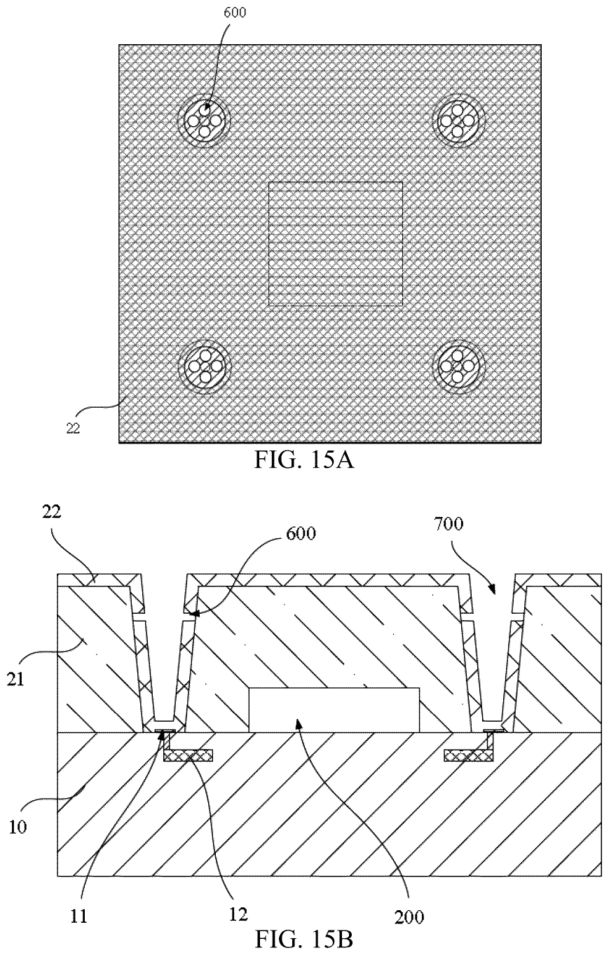

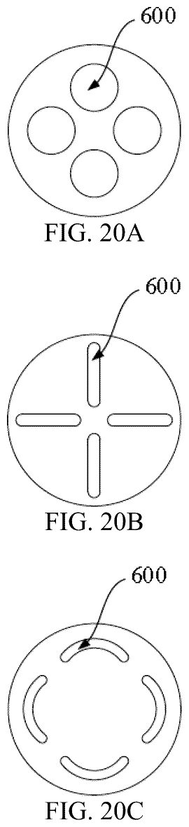

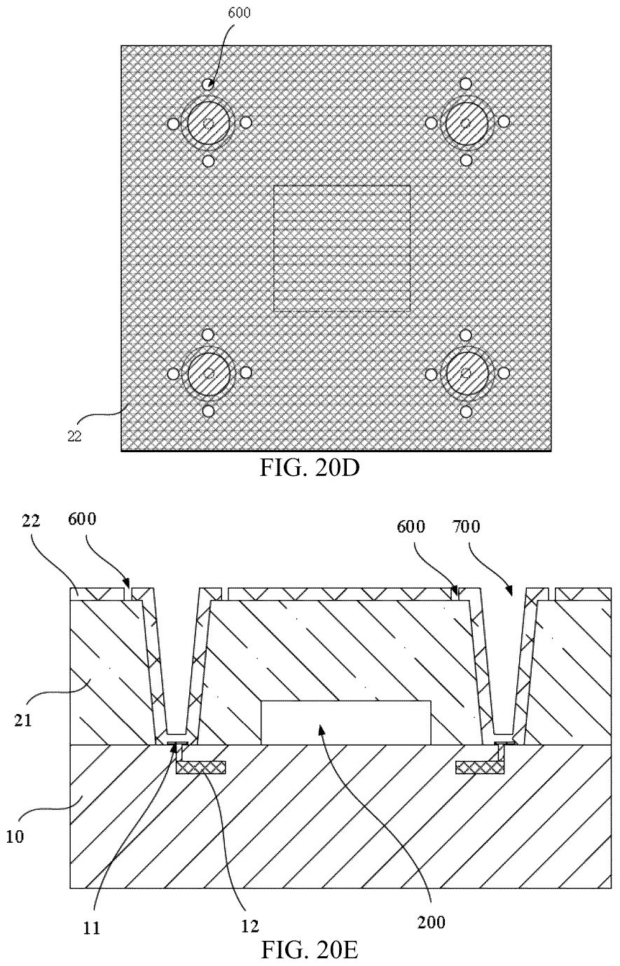

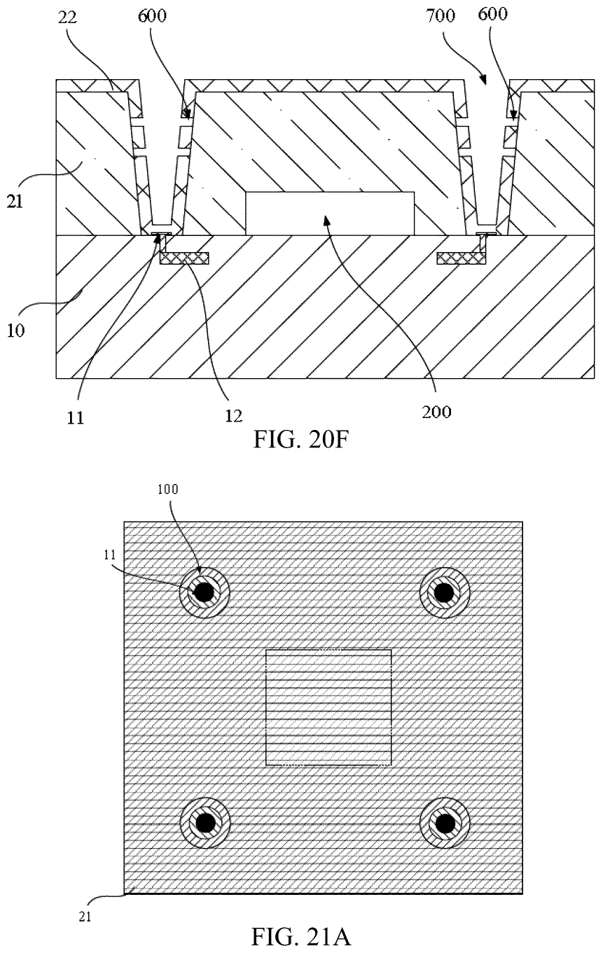

In an exemplary implementation, as shown in FIGS. 15A, 15B, 20A, 20B, and 20C, a plurality of grooves 600 are provided within the through-hole 100, and the plurality of grooves 600 are uniformly distributed around an axis of the through-hole 100 to ensure that stress can be uniformly released.

In an exemplary implementation, as shown in FIG. 20F, a plurality of grooves 600 are provided within the through-hole 100, and orthographic projections of some of the plurality of grooves 600 on the chip 10 overlap.

In an exemplary implementation, as shown in FIGS. 20D and 20E, at least one groove 600 is provided around the through-hole 100.

In an exemplary implementation, a plurality of grooves 600 are provided around the through-hole 100, and the plurality of grooves 600 are uniformly distributed around the axis of the through-hole 100 to ensure that stress can be uniformly released.

In an exemplary implementation, referring to FIGS. 20A, 20B, and 20C together, an orthographic projection of the groove 600 on the chip 10 is circular, linear, or arc-shaped.

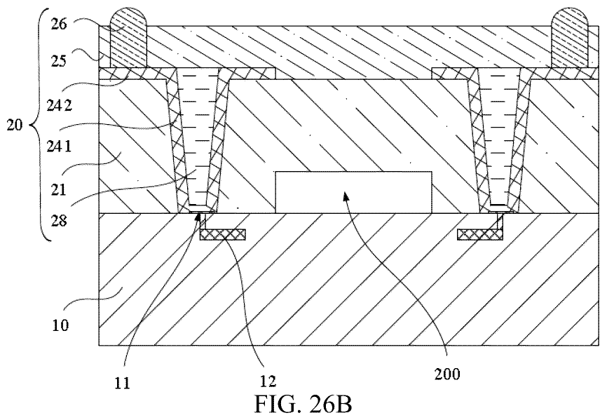

In an exemplary implementation, FIG. 26A is a schematic view of a planar structure of a sensor module after forming a connection electrode pattern in a further embodiment of the present application. FIG. 26B is a schematic view of a cross-sectional structure of the sensor module after forming the connection electrode pattern in a further embodiment of the present application, wherein the cross-section is perpendicular to the chip 10.

The stacked structures further include a filler 28 provided on a side of the first conductive portion 241 away from the chip 10 and closing the side of the through-hole 100 away from the chip 10.

The cavity 700 is filled with a filling material, and the side of the through-hole 100 away from the chip 10 is closed. A thermal expansion coefficient of a material of the filler 28 is negative. In this way, by filling the cavity 700 with a material with a negative thermal expansion coefficient, the stress of the first conductive portion 241 can be neutralized, and at the same time, the through-hole 100 can be filled so that the side of the through-hole 100 away from the chip 10 is flat. In this way, the photoresist can be homogenized normally by spin coating, spraying, etc., and the thickness of the photoresist at the through-hole 100 is normal, so that the photoresist can be prevented from accumulating in the through-holes 100. This accumulation could lead to the loss or thinness of the photoresist at the side of the through-hole 100 away from the chip 10, and cause partial etching of the first conductive portion 241 at the side of the through-hole 100 away from the chip 10 during etching, resulting in abnormal electrical conduction at the position of the through-hole 100.

The following is an exemplary illustration through the manufacturing process of the sensor module. A “patterning process” mentioned in the present application includes a treatment such as deposition of a film layer, photoresist coating on a film layer, mask exposure, development, etching, and photoresist stripping for a metal material, an inorganic material, or a transparent conductive material, and includes a treatment such as organic material coating, mask exposure, and development etc. for an organic material. Deposition may be any one or more of sputtering, evaporation, chemical vapor deposition, and electroplate, and coating may be any one or more of spray coating, spin coating, and inkjet printing, and etching may be any one or more of dry etching and wet etching. The present application is not limited thereto. A “thin film” refers to a layer of thin film made of a certain material on a base substrate using deposition, coating, or other processes. If the “thin film” does not need to be processed through a patterning process in the entire manufacturing process, the “thin film” may also be called a “layer”. If the “thin film” needs to be processed through the patterning process in the entire manufacturing process, the “thin film” is called a “thin film” before the patterning process is performed and is called a “layer” after the patterning process is performed. At least one “pattern” is contained in the “layer” which has been processed through the patterning process. “A and B are provided on a same layer” in the present application means that A and B are formed simultaneously through the same patterning process. The “thickness” of the film layer is the dimension of the film layer in a direction perpendicular to the base substrate. In an exemplary implementation of the present application, “an orthographic projection of B is within a range of an orthographic projection of A” or “an orthographic projection of A contains an orthographic projection of B” means that a boundary of the orthographic projection of B falls within a range of a boundary of the orthographic projection of A, or the boundary of the orthographic projection of A overlaps with the boundary of the orthographic projection of B.

The manufacturing process of the sensor module in an exemplary embodiment of the present application may include the following operations.
1. Manufacturing a chip 10. In an exemplary implementation, the chip 10 may be a piezoresistive chip. The chip 10 may include at least one electrode part 11 and at least one piezoresistor 12. Piezoresistors 12 are connected to electrode parts 11 in a one-to-one correspondence.

In an exemplary implementation, the electrode part 11 is provided on a surface of the chip 10.

In an exemplary implementation, a material of the electrode part 11 includes, but is not limited to, gold (Au), copper (Cu), molybdenum (Mo), aluminum (Al), and the like.

The chip 10 may be manufactured using conventional processes, which will not be described here.
2. Forming a base substrate pattern. The base substrate 21 may be a glass base substrate. In an exemplary implementation, forming the base substrate 21 pattern may include forming the base substrate 21 pattern on the base substrate 21 by sandblasting method, photosensitive glass method, focused discharge method, plasma etching method, laser ablation, electrochemical and laser induced etching method. The base substrate 21 pattern may include a plurality of through-holes 100 and at least one slot structure 200. The through-holes 100 penetrate the base substrate 21 in a direction perpendicular to the chip 10 and correspond to the positions of the electrode parts 11, so that the electrode parts 11 are exposed to the through-holes 100. The slot structure 200 is provided on a side of the base substrate 21 close to the chip 10.

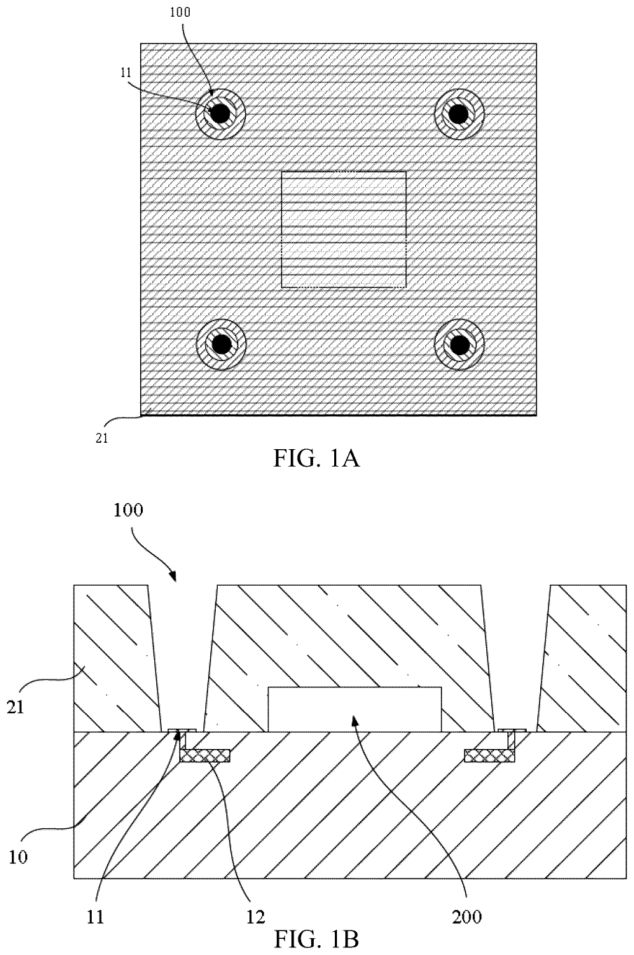

A surface of the base substrate 21 close to the chip 10 is connected to the surface of the chip 10, so that an orthographic projection of a through-hole 100 on the chip 10 overlaps at least partially with the electrode part 11, allowing the electrode part 11 to be exposed and enabling the chip 10 to close the slot structure 200 to form a sealing cavity, as shown in FIGS. 1A and 1B. FIG. 1A is a schematic view of a planar structure of a sensor module after forming a base substrate 21 pattern in an embodiment of the present application. FIG. 1B is a schematic view of a cross-sectional structure of the sensor module after forming the base substrate 21 pattern in an embodiment of the present application, wherein the cross-section is perpendicular to the chip 10.

In an exemplary implementation, the surface of the base substrate 21 close to the chip 10 is anodically bonded to the surface of the chip 10.

In an exemplary implementation, a cross-sectional shape of the through-hole 100 in a plane parallel to the chip 10 may be, but is not limited to, a circle, a triangle, a square, a rectangle, or the like.

In an exemplary implementation, taking as an example that the cross-sectional shape of the through-hole 100 in the plane parallel to the chip 10 is circular, a diameter of the through-hole 100 may be about 50 μm to 300 μm. For example, the diameter of the through-hole 100 may be about 175 μm.

In an exemplary implementation, a depth of the through-hole 100 may be from about 200 μm to 400 μm, and the depth may be a dimension in a direction perpendicular to the plane of the chip 10. For example, the depth of the through-hole 100 may be about 200 μm.

In an exemplary implementation, a hole wall of the through-hole 100 has a taper, so that a cross section of the through-hole 100 along a direction perpendicular to the chip 10 has a large-sized end and a small-sized end. The large-sized end is located on a side of the through-hole 100 away from the chip 10, and the small-sized end is located on a side of the through-hole 100 close to the chip 10. By providing the hole wall of the through-hole 100 in the above-described structure, it is convenient to deposit material on the hole wall of the through-hole 100. The diameter of the through-hole 100 may be the diameter of the large-sized end, the diameter of the small-sized end, or the average diameter, which is not limited in the present application.

In an exemplary implementation, the slot structure 200 may have a depth of about 40 μm to 240 μm, and the depth may be a dimension in a direction perpendicular to the plane of the chip 10. For example, the slot depth of the slot structure 200 may be about 140 μm. It can be understood that in other embodiments, the slot depth of the slot structure 200 may be in other numerical ranges and may be designed according to the deformation distance of the sensor module.

In an exemplary implementation, a cross-sectional shape of the slot structure 200 parallel to the chip 10 may be, but is not limited to, a circle, triangle, square, rectangle, or the like.

In an exemplary implementation, taking the cross-sectional shape of the slot structure 200 parallel to the chip 10 as a square as an example, a side length of the slot structure 200 may be about 100 μm to 600 μm. For example, the side length of the slot structure 200 may be about 350 μm.

In an exemplary implementation, the orthographic projection of the through-hole 100 on the chip 10 does not overlap with an orthographic projection of the slot structure 200 on the chip 10.

In an exemplary implementation, the number of electrode parts 11 is plural, the number of through-holes 100 corresponds to the number of electrode parts 11, and the plurality of through-holes 100 and the plurality of electrode parts 11 are in a one-to-one correspondence. The plurality of through-holes 100 are provided around the slot structure 200, and a distance between a circumference of the slot structure 200 and a circumference of the through-holes 100 is greater than or equal to the side length of the slot structure 200, so as to reduce the influence of deformation of the sensor module on the through-holes 100 and the structure provided on the hole wall of the through-holes 100.
3. Forming a first conductive layer 22. In an exemplary implementation, forming the first conductive layer 22 may include: electroplating a first conductive thin film at a first electroplating current on the base substrate 21 on which the foregoing pattern is formed to form a first conductive layer 22 on a side of the base substrate 21 away from the chip 10 and on the hole wall of the through-holes 100. The first conductive layer 22 is electrically connected to the electrode part 11, and the first conductive layer 22 in the through-holes 100 is in an unfilled state and forms cavities 700, which correspond one-to-one with the through-holes 100 and are located in the corresponding through-holes 100, as shown in FIGS. 2A and 2B. FIG. 2A is a schematic planar view of a sensor module after forming a first conductive layer in an embodiment of the present application. FIG. 2B is a schematic cross-sectional view of the sensor module after forming the first conductive layer in an embodiment of the present application, wherein the cross-section is perpendicular to the chip 10.

In an exemplary implementation, a material of the first conductive thin film may include, but is not limited to, a metal that is electrically conductive and can be electroplated and deposited, such as copper (Cu), nickel (Ni), chromium (Cr), or zinc (Zn).

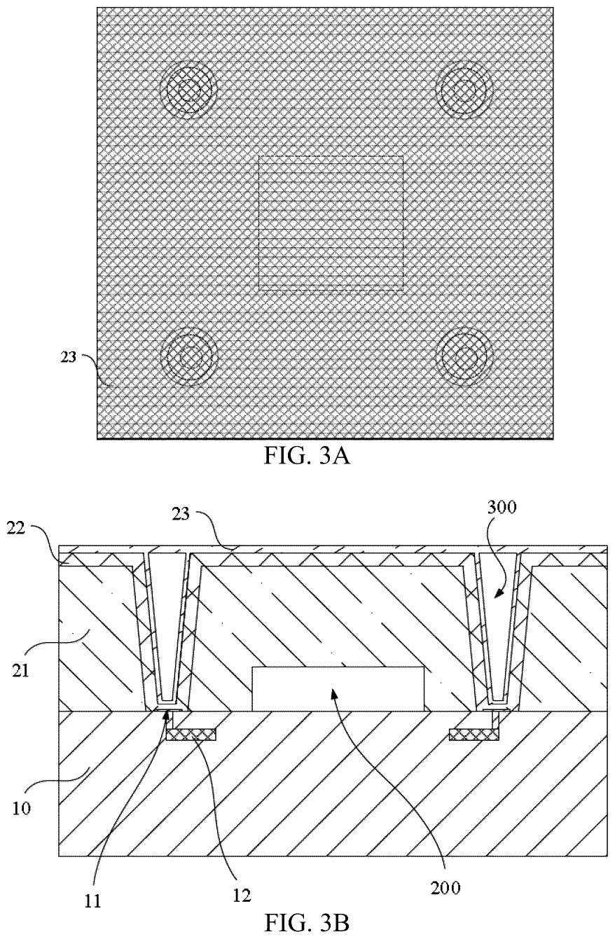

In an exemplary implementation, a thickness of the first conductive layer 22 may be about 3 μm to 7 μm, and the time for electroplating the first conductive thin film may be about 3 hours to 7 hours. For example, the thickness of the first conductive layer 22 may be about 5 μm, and the time for electroplating the first conductive thin film may be about 5 hours. In this way, the first conductive thin film can be slowly formed on the side of the base substrate 21 away from the chip 10 and the hole wall of the through-holes 100, so that the first conductive thin film can grow on the base substrate 21 towards a side away from the chip 10, and grow on the hole wall of the through-holes 100 towards the axis of the through-holes 100. The cavity 700 can maintain the through-holes 100 in an unfilled state, which not only ensures the electrical conductivity characteristics of the first conductive layer 22 in the through-holes 100, but also realizes electrical connection with the chip 10. At the same time, the slow growth of the first conductive thin film and the unfilled state of the through-holes 100 make the first conductive layer 22 conducive to stress release in time and space, and avoid cracks or even breakage at the positions of the through-holes 100 due to excessive stress in the first conductive layer 22.
4. Forming a second conductive layer 23. In an exemplary implementation, forming the second conductive layer 23 may include: electroplating a second conductive thin film at a second electroplating current on the base substrate 21 on which the foregoing patterns are formed to form a second conductive layer 23 on a side of the first conductive layer 22 away from the chip 10, the second conductive layer 23 closing a side of the through-holes 100 away from the chip 10, as shown in FIGS. 3A and 3B. FIG. 3A is a schematic planar view of a sensor module after forming a second conductive layer in an embodiment of the present application. FIG. 3B is a schematic cross-sectional view of the sensor module after forming the second conductive layer in an embodiment of the present application, wherein the cross-section is perpendicular to the chip 10.

In an exemplary implementation, a material of the second conductive thin film may include, but is not limited to, a metal that is electrically conductive and can be electroplated and deposited, such as copper (Cu), nickel (Ni), chromium (Cr), or zinc (Zn).

In an exemplary implementation, the material of the first conductive thin film and the material of the second conductive thin film may be the same or different.

In an exemplary implementation, a thickness of the second conductive layer 23 may be about 2 μm to 4 μm, and the time of electroplating the second conductive thin film may be about 20 min to 40 min, for example, the thickness of the second conductive layer 23 may be about 3 μm, and the time of electroplating the second conductive thin film may be about 30 min. In this way, by electroplating the second conductive thin film, the side of the through-holes away from the chip 10 can be closed, so that the side of the through-holes 100 away from the chip 10 is flat. In this way, the photoresist can be homogenized normally by spin coating, spraying, etc., and the thickness of the photoresist at the through-holes 100 is normal, so that the photoresist can be prevented from accumulating in the through-holes 100. This accumulation could lead to the loss or thinness of the photoresist at the side of the through-holes 100 away from the chip 10, and cause partial etching of the first conductive layer 22 at a mouth of the cavity 700 during etching, resulting in abnormal electrical conduction at the positions of the through-holes 100.

In an exemplary implementation, a first current used for electroplating the first conductive thin film is less than a second current used for electroplating the second conductive thin film. A ratio of the first current to the second current may be about 1:10 to 1:40. For example, the ratio of the first current to the second current may be about 1:25.

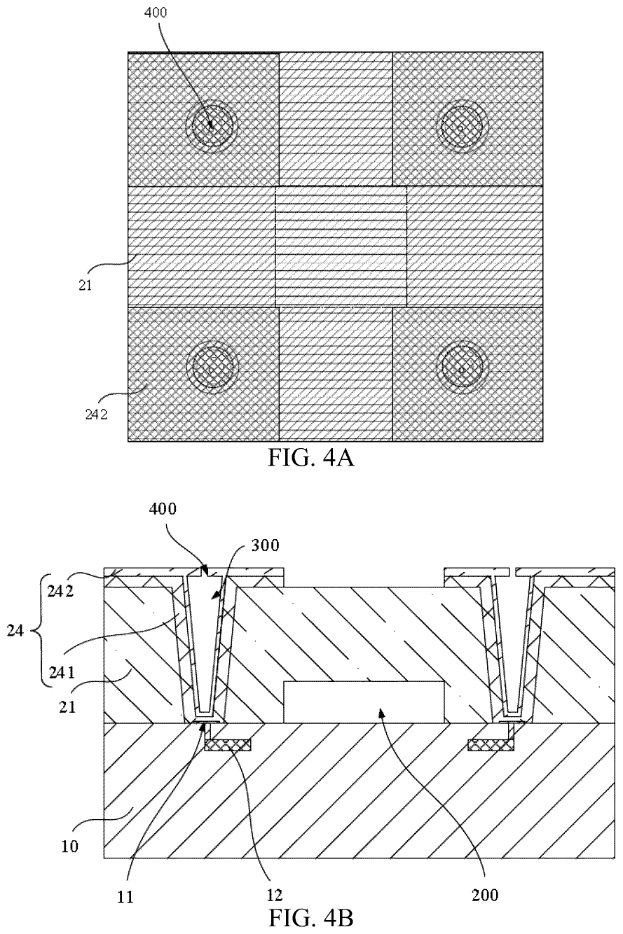

The electroplating of the first conductive thin film and the electroplating of the second conductive thin film adopt different electroplating currents, which is conducive to the stress release of the first conductive layer 22, and can quickly form the second conductive layer 23, thereby saving electroplating time and improving production efficiency.
5. Forming a conductive structure pattern. In an exemplary implementation, forming the conductive structure pattern may include: patterning the first conductive layer 22 and the second conductive layer 23 by a patterning process to form a conductive structure pattern provided on the side of the base substrate 21 away from the chip 10 and on the hole wall of the through-holes 100. The conductive structure pattern may include at least one conductive structure 24, and the conductive structure 24 may include a first conductive portion 241 and a second conductive portion 242. The first conductive portion 241 is provided on the side of the base substrate 21 away from the chip 10 and on the hole wall of the through-holes 100, and the first conductive portion 241 is connected to the electrode part 11. The second conductive portion 242 is provided on a side of the first conductive portion 241 away from the chip 10, and closes the through-holes 100 to form a closed chamber 300, as shown in FIGS. 4A and 4B. FIG. 4A is a schematic planar view of a sensor module after forming a conductive structure pattern in an embodiment of the present application. FIG. 4B is a schematic cross-sectional view of the sensor module after forming the conductive structure pattern in an embodiment of the present application, wherein the cross-section is perpendicular to the chip 10.

In an exemplary implementation, the second conductive portion 242 is provided with a via 400. The via 400 penetrates the second conductive portion 242 in a direction perpendicular to the chip 10, so as to communicate the chamber 300 with the outside. This prevents the electroplating solution from remaining in the chamber 300 after the through-holes 100 are closed, which could otherwise result in bad reliability.

In an exemplary implementation, a diameter of the via 400 may be about 10 μm to 20 μm, for example, the diameter of the via 400 may be about 15 μm. In this way, by setting the diameter of the via 400 to a smaller size, it is possible to prevent the second conductive part 242 from being collapsed by force and affecting the electrical conduction.

The first conductive portion 241 includes a conductive structure pattern located on the hole wall of the through-holes 100 after the first conductive layer 22 and the second conductive layer 23 are patterned.

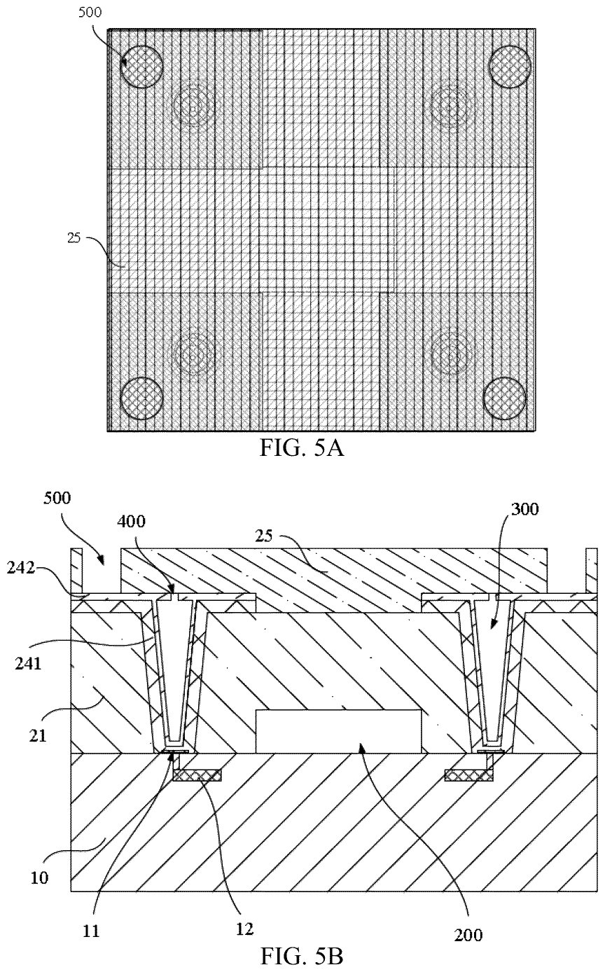

The second conductive portion 242 includes a conductive structure pattern provided on the side of the base substrate 21 away from the chip 10 after the first conductive layer 22 and the second conductive layer 23 are patterned.
6. Forming an insulation layer pattern. In an exemplary implementation, forming the insulation layer pattern may include: coating an insulation thin film on the base substrate 21 on which the foregoing patterns are formed, and patterning the insulation thin film by a patterning process to form an insulation layer 25 provided on a side of the conductive structure pattern away from the chip 10. The insulation layer 25 is provided with a connection hole 500, and the insulation thin film in the connection hole 500 is etched off, exposing the second conductive portion 242, as shown in FIGS. 5A and 5B. FIG. 5A is a schematic planar view of a sensor module after forming an insulation layer pattern in an embodiment of the present application. FIG. 5B is a schematic cross-sectional view of the sensor module after forming the insulation layer pattern in an embodiment of the present application, wherein the cross-section is perpendicular to the chip 10.

In an exemplary implementation, a material of the insulation thin film may include, but is not limited to, polyimide (PI), epoxy resin (EP), green oil, and the like, and may be a monolayer structure, or may be a multilayer structure. The insulation layer 25 can improve the water-oxygen resistance of the conductive layer pattern and prevent water and oxygen from dipping downward from the conductive layer into the base substrate 21 and the chip 10, affecting their electrical characteristics. At the same time, the insulation layer 25 made of the above material has ductility, and does not restrict the normal deformation of the sensor module, so that the sensor module can be normally deformed.

In an exemplary implementation, a thickness of the insulation layer 25 may be about 9 μm to 21 μm. For example, the thickness of the insulation layer 25 may be about 7 μm.

In an exemplary implementation, the number of connection holes 500 is consistent with and corresponds one-to-one with the number of second conductive portions 242.

In an exemplary implementation, a diameter of the connection hole 500 may be about 30 μm to 180 μm, for example, the diameter of the connection hole 500 may be about 100 μm.

In an exemplary implementation, a depth of the connection hole 500 may be about 9 μm to 21 μm, for example, the depth of the connection hole 500 may be about 10 μm.

In an exemplary implementation, an orthographic projection of the connection hole 500 on the chip 10 does not overlap with the orthographic projection of the through-hole 100 on the chip 10.
7. Forming a connection electrode pattern. In an exemplary implementation, forming the connection electrode pattern may include: on the base substrate 21 on which the foregoing patterns are formed, placing a connection electrode 26 in the connection hole 500 by welding, diffusion welding, sintering, or the like, and connecting the connection electrode 26 to the second conductive portion 242, so as to form the connection electrode pattern on a side of the insulation layer 25 away from the chip 10.

It can be understood that, in other embodiments, forming the connection electrode pattern may also include: depositing a connection electrode thin film on the chip 10 on which the foregoing patterns are formed, and patterning the connection electrode thin film by a patterning process to form the connection electrode pattern provided on the side of the insulation layer 25 away from the chip 10. The connection electrode pattern includes at least one connection electrode 26 provided within the connection hole 500 and electrically connected to the second conductive portion 242.

The second conductive portion 242 can be electrically connected to a printed circuit board through the connection electrode 26, so that the sensor module can transmit signals to the external components through the printed circuit board, as shown in FIGS. 6A and 6B. FIG. 6A is a schematic planar view of a sensor module after forming a connection electrode pattern in an embodiment of the present application. FIG. 6B is a schematic cross-sectional view of the sensor module after forming the connection electrode pattern in an embodiment of the present application, wherein the cross-section is perpendicular to the chip 10.

In an exemplary implementation, a material of connection electrode 26 may include, but is not limited to, copper (Cu), nickel (Ni), chromium (Cr), tin (Sn), zinc (Zn), and the like.

In an exemplary implementation, the number of connection electrodes 26 is consistent with and corresponds one-to-one with the number of the connection holes 500.

In an exemplary implementation, the connection electrode 26 fills the connection hole 500 and is partially outwardly protruded from a side of the insulation layer 25 away from the chip 10. The thickness of the connection electrode 26 protruding from the side of the insulation layer 25 away from the chip 10 may be about 9 μm to 21 μm. For example, the thickness of the connection electrode 26 protruding from the side of the insulation layer 25 away from the chip 10 may be about 10 μm.

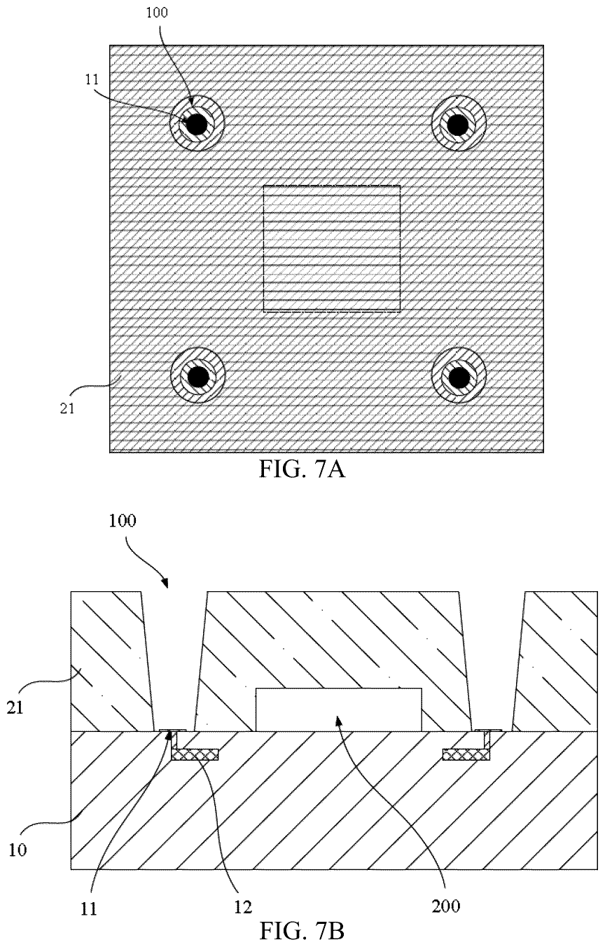

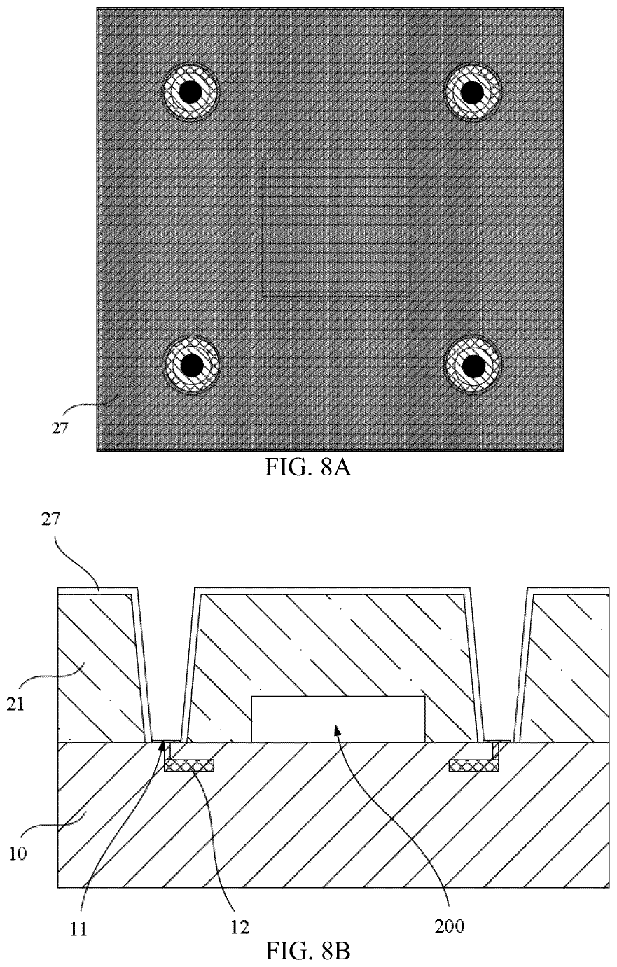

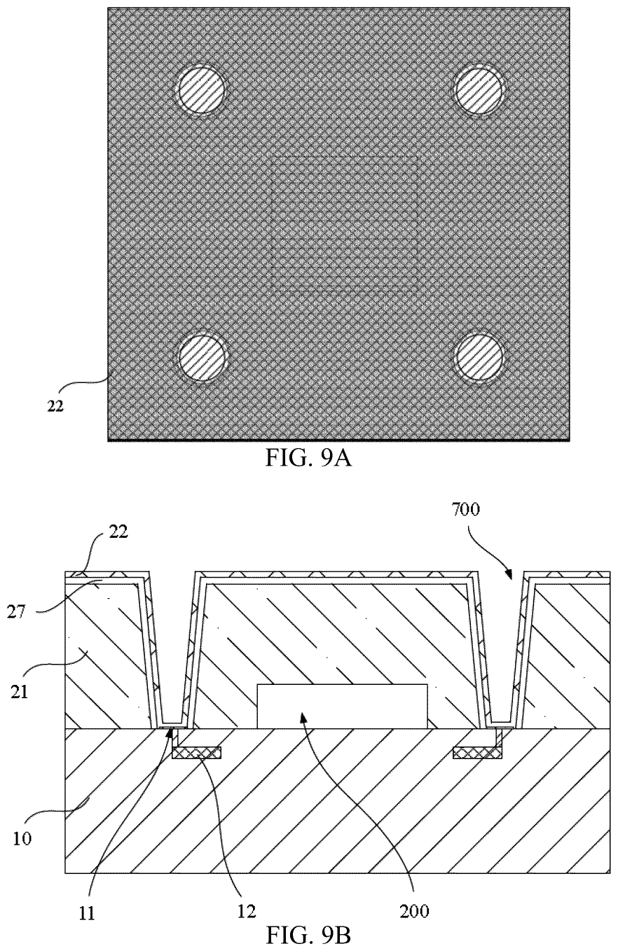

The manufacturing process of the sensor module in another exemplary embodiment of the present application may include the following operations.
1. Manufacturing a chip 10. In an exemplary implementation, the process of manufacturing the chip 10 and an electrode part 11 and a piezoresistor 12 of the formed chip 10 are substantially the same as in the foregoing embodiment.
2. Forming a base substrate pattern. In an exemplary implementation, the process of forming the base substrate pattern and the formed base substrate pattern are substantially the same as in the foregoing embodiment, as shown in FIGS. 7A and 7B. FIG. 7A is a schematic view of a planar structure of a sensor module after forming a base substrate pattern in another embodiment of the present application. FIG. 7B is a schematic view of a cross-sectional structure of the sensor module after forming the base substrate pattern in another embodiment of the present application, wherein the cross-section is perpendicular to the chip 10.
3. Forming a buffer layer 27. In an exemplary implementation, forming the buffer layer 27 may include: depositing a buffer thin film on the base substrate 21 on which the foregoing patterns are formed, and patterning the buffer thin film by a patterning process to form the buffer layer 27 on a side of the base substrate 21 away from the chip 10, as shown in FIGS. 8A and 8B. FIG. 8A is a schematic view of a planar structure of a sensor module after forming a buffer layer 27 in another embodiment of the present application. FIG. 8B is a schematic view of a cross-sectional structure of the sensor module after forming the buffer layer 27 in another embodiment of the present application, wherein the cross-section is perpendicular to the chip 10.
4. Forming a first conductive layer 22. In an exemplary implementation, forming the first conductive layer 22 may include: electroplating a first conductive thin film at a first electroplating current on the base substrate 21 on which the foregoing patterns are formed to form the first conductive layer 22 on a side of the buffer layer 27 away from the base substrate 21. The first conductive layer 22 is electrically connected to the electrode part 11, and the first conductive layer 22 in the through-holes 100 is in an unfilled state and forms cavities 700, which correspond one-to-one with the through-holes 100 and are located in the corresponding through-holes 100, as shown in FIGS. 9A and 9B. FIG. 9A is a schematic planar view of a sensor module after forming a first conductive layer in another embodiment of the present application. FIG. 9B is a schematic cross-sectional view of the sensor module after forming the first conductive layer in another embodiment of the present application, wherein the cross-section is perpendicular to the chip 10.

A thermal expansion coefficient of a material of the buffer layer 27 is between the thermal expansion coefficient of the glass (3.3 ppm/°C) and the thermal expansion coefficient of the material of the first conductive thin film (e.g., the thermal expansion coefficient of copper: 17.5 ppm/°C). In this way, by providing the buffer layer 27, the stress gradient between the base substrate 21 and the first conductive layer 22 can be reduced, and the risk of delamination between the base substrate 21 and the first conductive layer 22 can be reduced.

In an exemplary implementation, the material of the buffer layer 27 may include, but is not limited to, titanium (Ti) (8.6 ppm/°C), tungsten (W) (4.5 ppm/°C), platinum (Pt) (9 ppm/°C), biphenyl-type polyimide (4-8 ppm/°C), and the like.

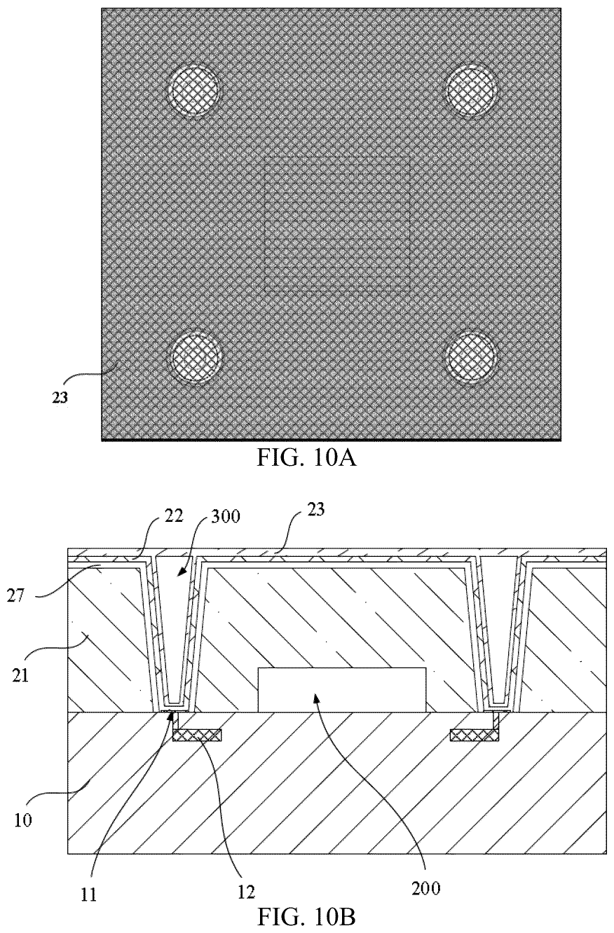

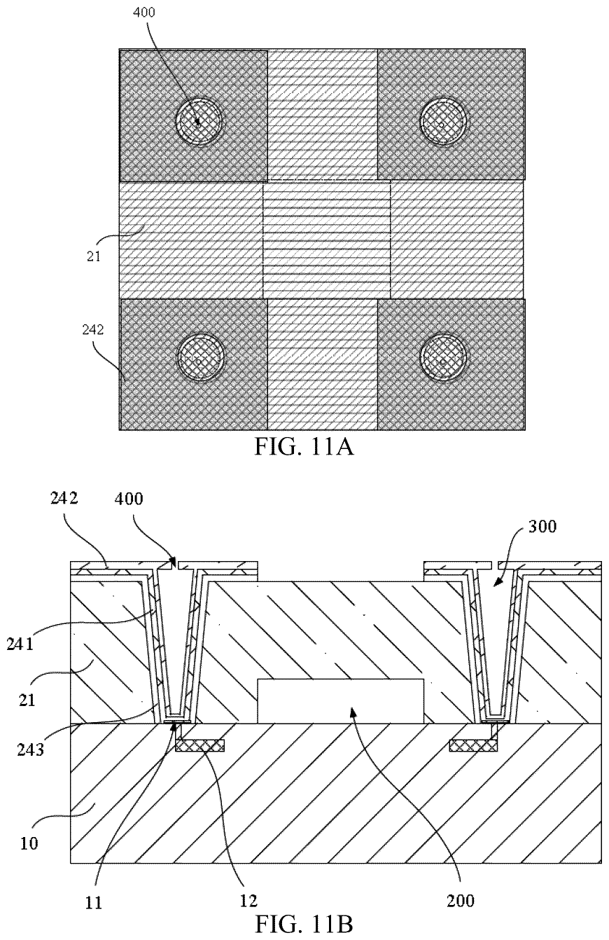

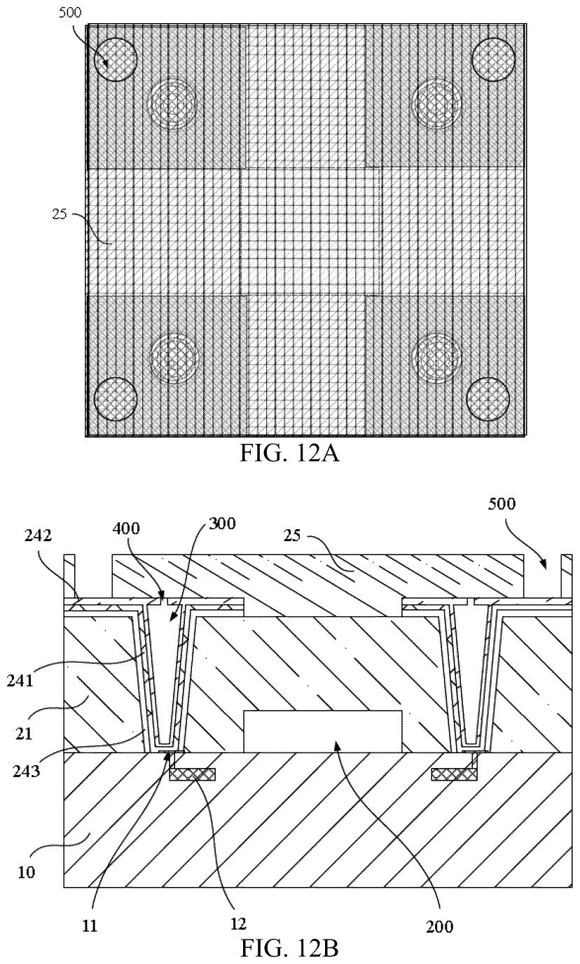

In an exemplary implementation, the buffer layer 27 may have a thickness of about 0.5 μm to about 2 μm, for example, the buffer layer 27 may have a thickness of about 1 μm.
5. Forming a second conductive layer. In an exemplary implementation, the process of forming the second conductive layer 23 and the formed second conductive layer 23 are substantially the same as in the foregoing embodiment, as shown in FIGS. 10A and 10B. FIG. 10A is a schematic view of a planar structure of a sensor module after forming a second conductive layer in another embodiment of the present application. FIG. 10B is a schematic view of a cross-sectional structure of the sensor module after forming the second conductive layer in another embodiment of the present application, wherein the cross-section is perpendicular to the chip 10.
6. Forming a conductive structure pattern. In an exemplary implementation, forming the conductive structure pattern may include: patterning the buffer layer 27, the first conductive layer 22, and the second conductive layer 23 by a patterning process to form a conductive structure pattern provided on the side of the base substrate 21 away from the chip 10 and on the hole wall of the through-holes 100. The conductive structure pattern may include at least one conductive structure 24 which may include a first conductive portion 241, a second conductive portion 242, and a buffer part 243. The buffer part 243 is provided on the side of the base substrate 21 away from the chip 10 and on the hole wall of the through-holes 100. The first conductive portion 241 is provided on a side of the buffer part 243 away from the chip 10. The second conductive portion 242 is provided on a side of the first conductive portion 241 away from the chip 10 and closes the through-hole 100 to form a closed chamber 300, as shown in FIGS. 11A and 11B. FIG. 11A is a schematic planar view of a sensor module after forming a conductive structure pattern in another embodiment of the present application. FIG. 11B is a schematic cross-sectional view of the sensor module after forming the conductive structure pattern in another embodiment of the present application, wherein the cross-section is perpendicular to the chip 10.
7. Forming an insulation layer pattern. In an exemplary implementation, the process of forming the insulation layer pattern and the formed insulation layer pattern are substantially the same as in the foregoing embodiment, as shown in FIGS. 12A and 12B. FIG. 12A is a schematic view of a planar structure of a sensor module after forming an insulation layer pattern in another embodiment of the present application. FIG. 12B is a schematic view of a cross-sectional structure of the sensor module after forming the insulation layer pattern in another embodiment of the present application, wherein the cross-section is perpendicular to the chip 10.
8. Forming a connection electrode pattern. In an exemplary implementation, the process of forming the connection electrode pattern and the formed connection electrode pattern are substantially the same as in the foregoing embodiment, as shown in FIGS. 13A and 13B. FIG. 13A is a schematic view of a planar structure of a sensor module after forming a connection electrode pattern in another embodiment of the present application. FIG. 13B is a schematic view of a cross-sectional structure of the sensor module after forming the connection electrode pattern in another embodiment of the present application, wherein the cross-section is perpendicular to the chip 10.

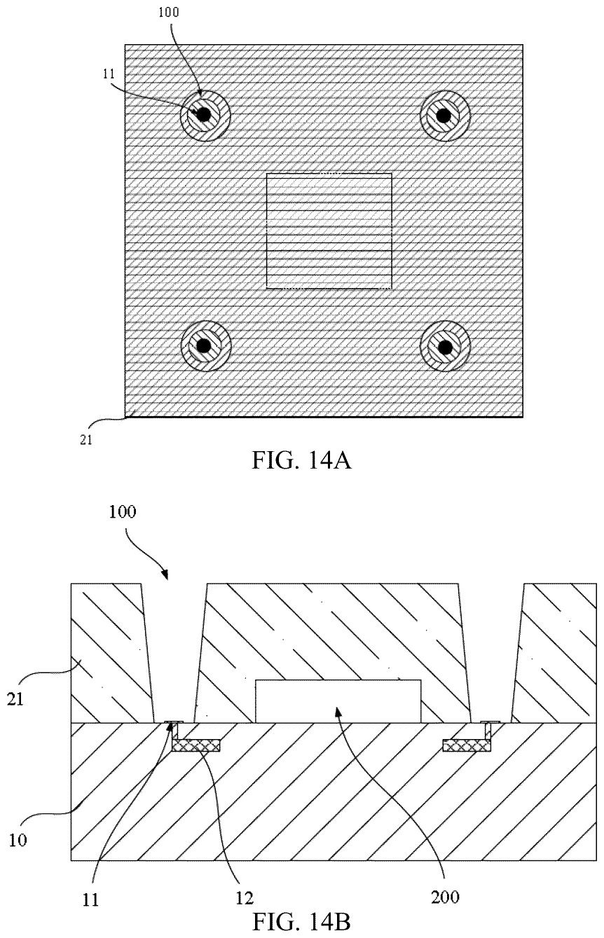

The manufacturing process of the sensor module in yet another exemplary embodiment of the present application may include the following operations.
1. Manufacturing a chip 10. In an exemplary implementation, the process of manufacturing the chip 10 and an electrode part 11 and a piezoresistor 12 of the formed chip are substantially the same as in the foregoing embodiment.
2. Forming a base substrate pattern. In an exemplary implementation, the process of forming the base substrate pattern and the formed base substrate pattern are substantially the same as in the foregoing embodiment, as shown in FIGS. 14A and 14B. FIG. 14A is a schematic view of a planar structure of a sensor module after forming a base substrate pattern in another embodiment of the present application. FIG. 14B is a schematic view of a cross-sectional structure of the sensor module after forming the base substrate pattern in another embodiment of the present application, wherein the cross-section is perpendicular to the chip 10.
3. Forming a first conductive layer pattern. In an exemplary implementation, forming the conductive layer pattern may include: electroplating a first conductive thin film at a first electroplating current on a base substrate 21 on which the foregoing patterns are formed, and patterning the first conductive thin film by a patterning process to form a first conductive layer 22 provided on the side of the base substrate 21 away from the chip 10 and on the hole wall of the through-holes 100. The first conductive layer 22 is electrically connected to the electrode part 11, and the first conductive layer 22 in the through-holes 100 is in an unfilled state and forms cavities700, which correspond one-to-one with the through-holes 100 and are located in the corresponding through-holes 100, as shown in FIGS. 15A and 15B. FIG. 15A is a schematic planar view of a sensor module after forming a first conductive layer pattern in yet another embodiment of the present application. FIG. 15B is a schematic cross-sectional view of the sensor module after forming the first conductive layer pattern in yet another embodiment of the present application, wherein the cross-section is perpendicular to the chip 10.

The first conductive layer pattern has a groove 600, and at least one groove 600 is provided within and/or around the through-holes 100. The arrangement of the groove 600 does not affect the electrical conductivity characteristics of the first conductive layer 22. Through the arrangement of the groove 600, when the stress of the first conductive layer 22 increases during the subsequent manufacturing process, the stress of the first conductive layer 22 can be first released at the groove 600, resulting in partial delamination and warping around the groove 600, thereby reducing the influence on the adhesion and electrical conductivity of the overall film layer of the first conductive layer 22.

In an exemplary implementation, the first conductive thin film within the groove 600 is at least partially etched off to form a hole structure or slot structure.

In an exemplary implementation, edges of the groove 600 are rounded to avoid the occurrence of structures such as right angles and sharp angles that are prone to cracks under stress.

In an exemplary implementation, as shown in FIGS. 15A, 15B, 20A, 20B, and 20C, a plurality of grooves 600 are provided within the through-hole 100, and the plurality of grooves 600 are uniformly distributed around the axis of the through-hole 100 to ensure that stress can be uniformly released.

In an exemplary implementation, as shown in FIG. 20F, a plurality of grooves 600 are provided within the through-hole 100, and orthographic projections of some of the plurality of grooves 600 on the chip 10 overlap. Some of the above grooves 600 are sequentially provided in a direction perpendicular to the chip.

In an exemplary implementation, as shown in FIGS. 20D and 20E, a plurality of grooves 600 are provided around the through-hole 100, and the plurality of grooves 600 are uniformly distributed around the axis of the through-hole 100 to ensure that stress can be uniformly released.

In an exemplary implementation, an orthographic projection of the groove 600 on the chip 10 may be, but is not limited to, circular, linear, or arc-shaped.

In an exemplary implementation, as shown in FIG. 20A, four grooves 600 are provided within the through-hole 100, and the four grooves 600 are uniformly distributed around the axis of the through-hole 100. The orthographic projection of the groove 600 on the chip 10 is circular.

In an exemplary implementation, as shown in FIG. 20B, four grooves 600 are provided within the through-hole 100, and the four grooves 600 are uniformly distributed around the axis of the through-hole 100. The orthogonal projection of the groove 600 on the chip 10 is linear, and the linear orthogonal projection is arranged along a radial direction of the through-hole 100, which can facilitate stress release in a direction perpendicular to radius.

In an exemplary implementation, as shown in FIG. 20C, four grooves 600 are provided within the through-hole 100, and the four grooves 600 are uniformly distributed around the axis of the through-hole 100. The orthographic projection of the groove 600 on the chip 10 is arc-shaped, and the arc-shaped orthographic projection is arranged in a radial direction perpendicular to the through-hole 100, which can facilitate stress release in a radius direction.

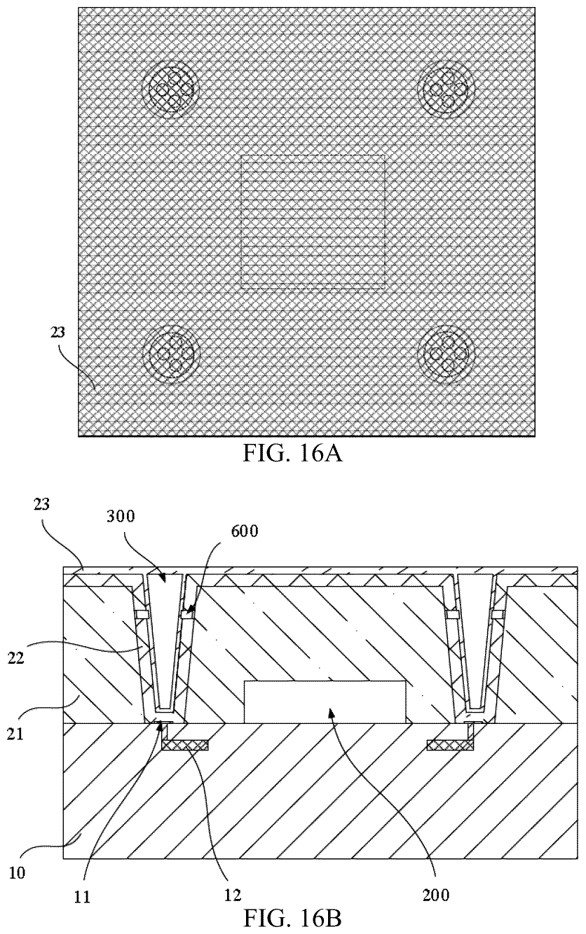

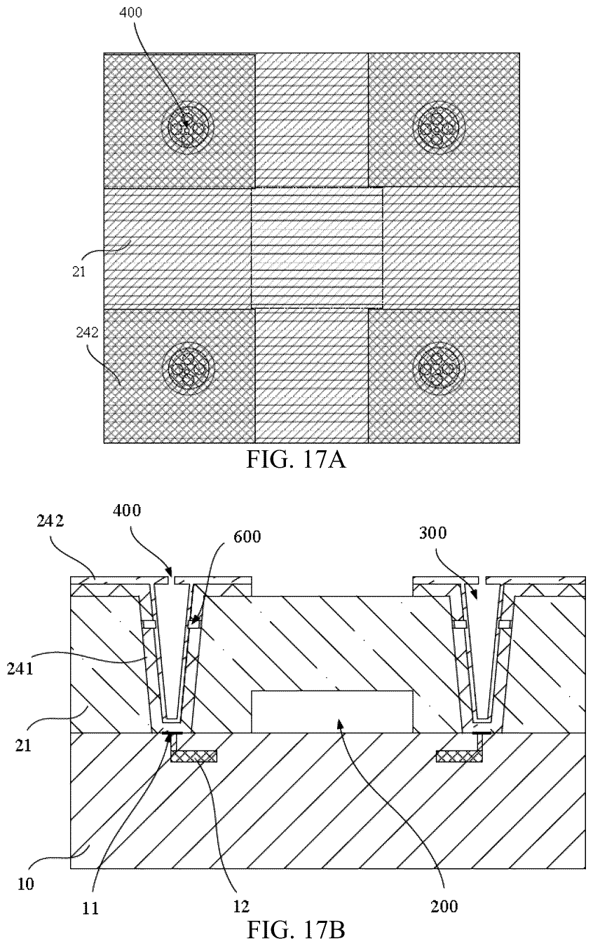

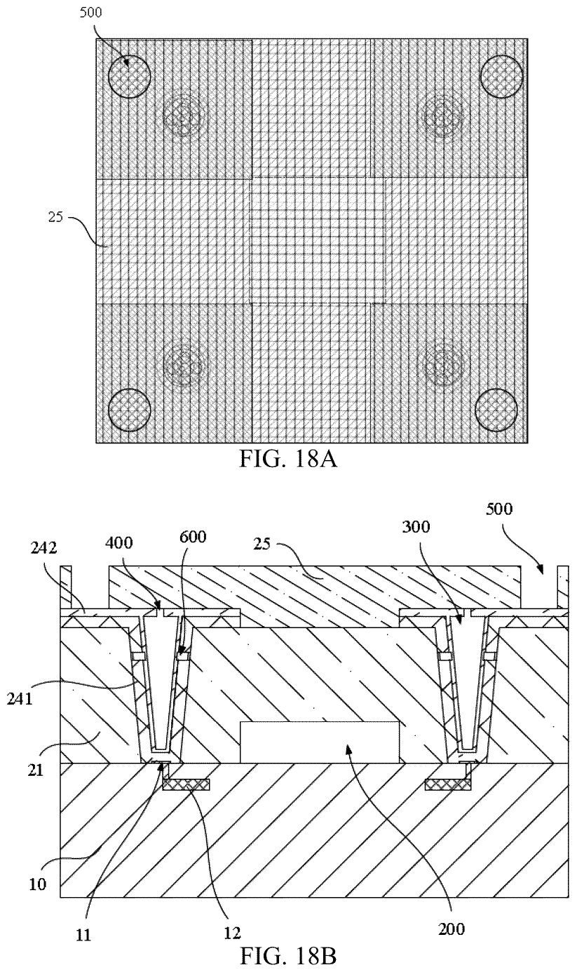

It can be understood that, in other embodiments, the position where the grooves 600 are provided on the first conductive layer 22, the number of the grooves 600, the distribution manner and density of the grooves 600, the direction in which the grooves 600 are provided relative to the radial direction of the through-holes 100, and the shape of the orthogonal projection of the grooves 600 on the chip 10 can be adjusted and designed according to the direction in which the stress release of the first conductive layer 22 is severe.
4. Forming a second conductive layer 23. In an exemplary implementation, forming the second conductive layer 23 may include: electroplating a second conductive thin film at a second electroplating current on the base substrate 21 on which the foregoing patterns are formed to form a second conductive layer 23 on a side of the first conductive layer 22 away from the chip 10. The second conductive layer 23 closes the side of the through-holes 100 away from the chip 10, and the formed second conductive layer 23 also is able to partially fill the groove 600 and/or close a mouth of the groove 600, as shown in FIGS. 16A and 16B. FIG. 16A is a schematic planar view of a sensor module after forming a second conductive layer in yet another embodiment of the present application. FIG. 16B is a schematic cross-sectional view of the sensor module after forming the second conductive layer in yet another embodiment of the present application, wherein the cross-section is perpendicular to the chip 10.
5. Forming a conductive structure pattern. In an exemplary implementation, the process of forming the conductive structure pattern and the formed conductive structure pattern are substantially the same as in the foregoing embodiment, as shown in FIGS. 17A and 17B. FIG. 17A is a schematic view of a planar structure of a sensor module after forming a conductive structure pattern in another embodiment of the present application. FIG. 17B is a schematic view of a cross-sectional structure of the sensor module after forming the conductive structure pattern in another embodiment of the present application, wherein the cross-section is perpendicular to the chip 10.
6. Forming an insulation layer pattern. In an exemplary implementation, the process of forming the insulation layer pattern and the formed insulation layer pattern are substantially the same as in the foregoing embodiment, as shown in FIGS. 18A and 18B. FIG. 18A is a schematic view of a planar structure of a sensor module after forming an insulation layer pattern in yet another embodiment of the present application. FIG. 18B is a schematic view of the cross-sectional structure of the sensor module after forming the insulation layer pattern in yet another embodiment of the present application, wherein the cross-section is perpendicular to the chip 10.
7. Forming a connection electrode pattern. In an exemplary implementation, the process of forming the connection electrode pattern and the formed connection electrode pattern are substantially the same as in the foregoing embodiment, as shown in FIGS. 19A and 19B. FIG. 19A is a schematic view of a planar structure of a sensor module after forming a connection electrode pattern in yet another embodiment of the present application. FIG. 19B is a schematic view of a cross-sectional structure of the sensor module after forming the connection electrode pattern in yet another embodiment of the present application, wherein the cross-section is perpendicular to the chip 10.

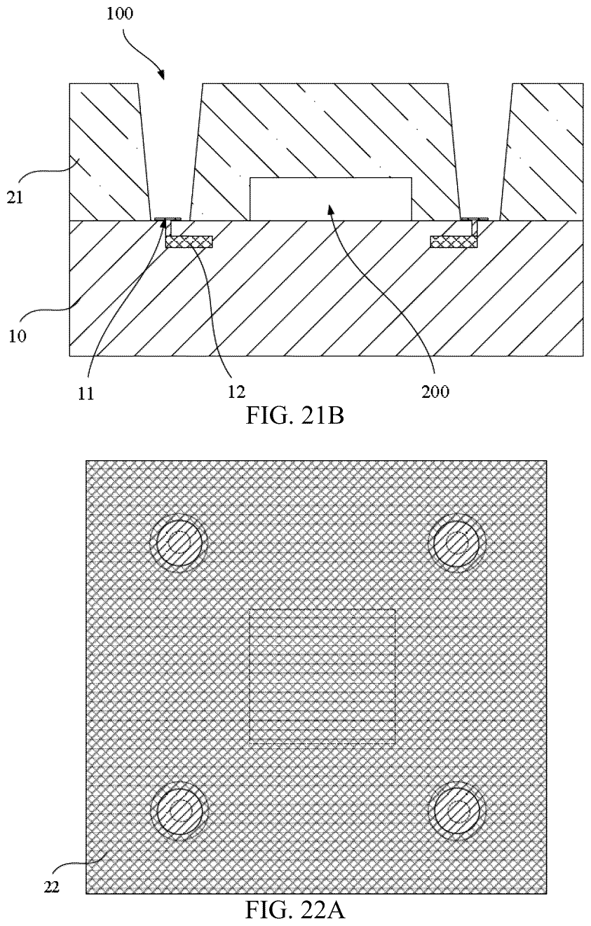

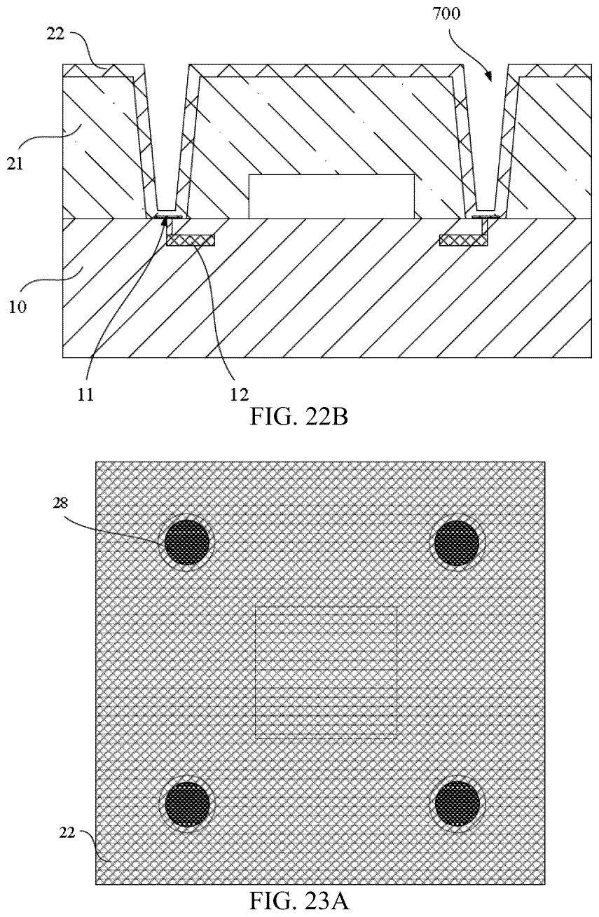

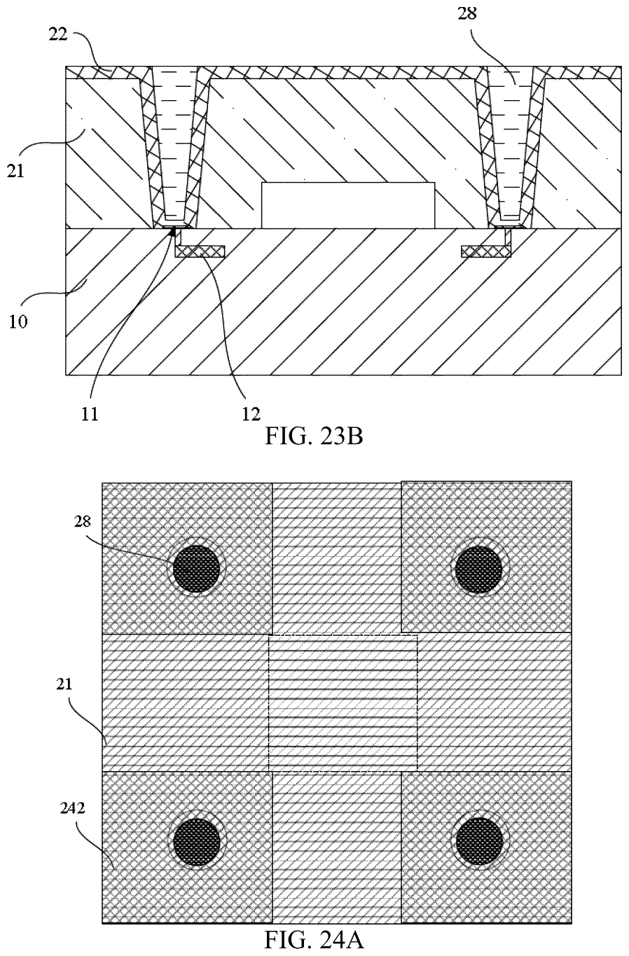

The manufacturing process of the sensor module in further exemplary embodiment of the present application may include the following operations.
1. Manufacturing a chip 10. In an exemplary implementation, the process of manufacturing the chip 10, and an electrode part 11 and a piezoresistor 12 of the formed chip 10 are substantially the same as in the foregoing embodiment.
2. Forming a base substrate pattern. In an exemplary implementation, the process of forming the base substrate pattern and the formed base substrate pattern are substantially the same as in the foregoing embodiment, as shown in FIGS. 21A and 21B. FIG. 21A is a schematic view of a planar structure of a sensor module after forming a base substrate pattern in a further embodiment of the present application. FIG. 21B is a schematic view of a cross-sectional structure of the sensor module after forming the base substrate pattern in a further embodiment of the present application, wherein the cross-section is perpendicular to the chip 10.
3. Forming a first conductive layer 22. In an exemplary implementation, the process of forming the first conductive layer 22 and the formed first conductive layer 22 are substantially the same as in the foregoing embodiment, as shown in FIGS. 22A and 22B. FIG. 22A is a schematic view of a planar structure of a sensor module after forming a first conductive layer in a further embodiment of the present application. FIG. 22B is a schematic view of a cross-sectional structure of the sensor module after forming the first conductive layer in a further embodiment of the present application, wherein the cross-section is perpendicular to the chip 10.
4. Forming a filling structure layer. In an exemplary implementation, forming the filling structure layer may include: filling a filler 28 on the base substrate 21 on which the foregoing patterns are formed to fill the cavity 700, and closing the side of the through-holes 100 away from the chip 10 to form the filling structure layer on a side of the first conductive layer 22 away from the chip 10, as shown in FIGS. 23A and 23B. FIG. 23A is a schematic view of a planar structure of a sensor module after forming a filling structure layer in a further embodiment of the present application. FIG. 23B is a schematic view of a cross-sectional structure of the sensor module after forming the filling structure layer in a further embodiment of the present application, wherein the cross-section is perpendicular to the chip 10.

A thermal expansion coefficient of a material of the filler 28 is negative. In this way, by filling the cavity 700 with a material with a negative thermal expansion coefficient, the stress of the first conductive layer 22 can be neutralized, and at the same time, the through-holes 100 can be filled so that the side of the through-holes 100 away from the chip 10 is flat. In this way, the photoresist can be homogenized normally by spin coating, spraying, etc., and the thickness of the photoresist at the through-holes 100 is normal, so that the photoresist can be prevented from accumulating in the through-holes 100. This accumulation could lead to the loss and thinness of the photoresist at the side of the through-holes 100 away from the chip 10, and cause partial etching of the first conductive layer 22 at the side of the through-holes 100 away from the chip 10 during etching, resulting in abnormal electrical conduction at the positions of the through-holes 100.

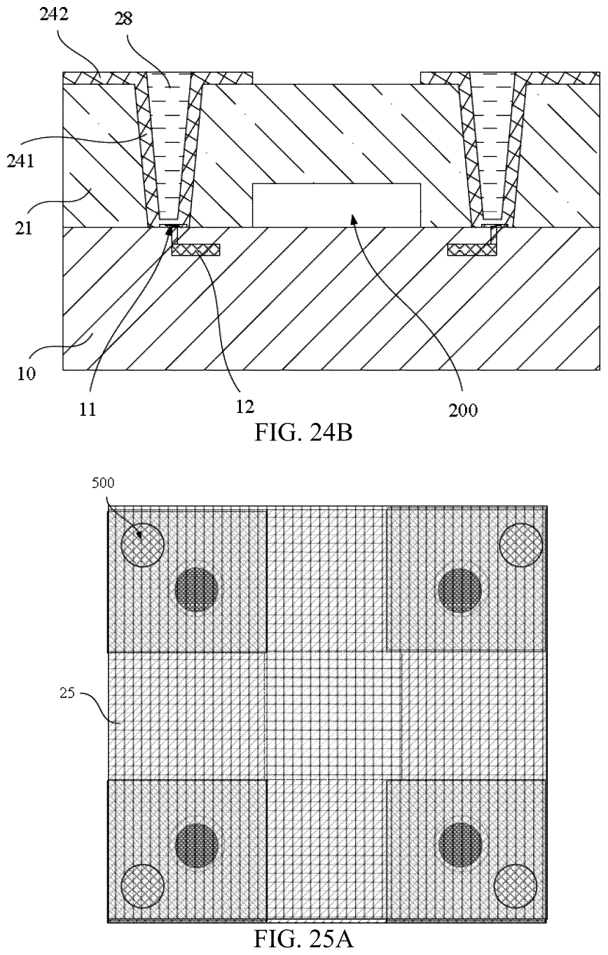

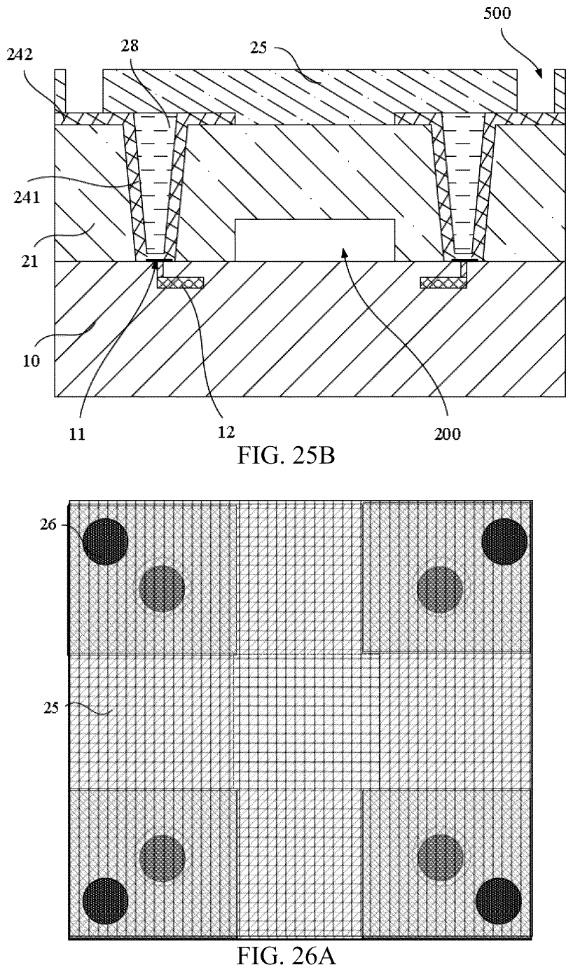

In an exemplary implementation, the material of the filler 28 may include, but is not limited to, an anti-perovskite structural material, a lead titanate-based compound material, or a silicone resin material.
5. Forming a conductive structure pattern. In an exemplary implementation, forming the conductive structure pattern may include: patterning the first conductive layer by a patterning process to form a conductive structure pattern provided on a side of the base substrate 21 away from the chip 10 and on a hole wall of the through-holes 100. The conductive structure pattern may include at least one conductive structure 24, and the conductive structure 24 may include a first conductive portion 241. The first conductive portion 241 is provided on the side of the base substrate 21 away from the chip 10 and on the hole wall of the through-holes 100. The first conductive portion 241 is connected to the electrode part 11, as shown in FIGS. 24A and 24B. FIG. 24A is a schematic planar view of a sensor module after forming a conductive structure pattern in a further embodiment of the present application. FIG. 24B is a schematic cross-sectional view of the sensor module after forming the conductive structure pattern in a further embodiment of the present application, wherein the cross-section is perpendicular to the chip 10.
6. Forming an insulation layer pattern. In an exemplary implementation, the process of forming the insulation layer pattern and the formed insulation layer pattern are substantially the same as in the foregoing embodiment, as shown in FIGS. 25A and 25B. FIG. 25A is a schematic view of a planar structure of a sensor module after forming an insulation layer pattern in a further embodiment of the present application. FIG. 25B is a schematic view of a cross-sectional structure of the sensor module after forming the insulation layer pattern in a further embodiment of the present application, wherein the cross-section is perpendicular to the chip 10.
7. Forming a connection electrode pattern. In an exemplary implementation, the process of forming the connection electrode pattern and the formed connection electrode pattern are substantially the same as in the foregoing embodiment, as shown in FIGS. 26A and 26B. FIG. 26A is a schematic view of a planar structure of a sensor module after forming a connection electrode pattern in a further embodiment of the present application. FIG. 26B is a schematic view of a cross-sectional structure of the sensor module after forming the connection electrode pattern in a further embodiment of the present application, wherein the cross-section is perpendicular to the chip 10.

The structure of the substrate in an exemplary embodiment of the present application and the manufacturing process thereof are only an exemplary illustration. In an exemplary implementation, a corresponding structure may be changed and patterning processes may be increased or decreased according to actual needs.

An exemplary embodiment of the present application also provides a manufacturing method of a substrate. In an exemplary implementation, a manufacturing method of a substrate may include: providing a base substrate 21 connected to a chip 10; forming a plurality of through-holes 100 on the base substrate 21, the through-holes 100 penetrating the base substrate 21 in a direction perpendicular to the chip 10; and forming stacked structures sequentially within the through-holes 100 in a direction perpendicular to and away from the base substrate 21. Thermal expansion coefficients of each layer in the laminated structures are different, and the stacked structures include a first conductive portion 241 electrically connected to the chip 10.

In an exemplary implementation, the manufacturing method of the substrate may also include forming a cavity 700 on a side of the first conductive portion 241 away from the chip 10.

In an exemplary implementation, the manufacturing method of the substrate may further include forming a second conductive portion 242 on a side of the first conductive portion 241 away from the chip 10, and closing a side of the through-holes away from the chip 10. The first conductive portion 241 and the second conductive portion 242 jointly enclose a chamber 300.

In an exemplary implementation, the manufacturing method of the substrate may further include: forming a via 400 on the second conductive portion 242, the via 400 penetrating the second conductive portion 242 in a direction perpendicular to the chip 10 and communicating with the chamber 300.

In an exemplary implementation, the first conductive portion 241 is electroplated at least on the hole wall of the through-holes 100 and on the chip 10 exposed to the through-holes 100 by a first electroplating current. The second conductive portion 242 is electroplated on a side of the first conductive portion 241 away from the chip 10 by a second electroplating current. The first electroplating current is less than the second electroplating current.

In an exemplary implementation, forming the stacked structures sequentially within the through-holes 100 in the direction perpendicular to and away from the base substrate 21 may include: forming a buffer layer 27 on a side of the base substrate away from the chip 10; and forming the first conductive portion 241 on a side of the buffer layer 27 away from the chip 10.

In an exemplary implementation, the manufacturing method of the substrate may further include forming a groove on the first conductive portion 241.

In an exemplary implementation, the manufacturing method of the substrate further includes: forming filler 28 on a side of the first conductive portion 241 away from the chip 10.

An embodiment of the present application also provides a sensor module, including the substrate and the chip 10 of the aforementioned embodiment. The surface of the base substrate close to the chip 10 is bonded to the surface of the chip 10. In an embodiment of the present application, the sensor module may be, but is not limited to, a pressure sensing module, an acceleration sensing module, an inertial measurement module, an angular motion detection module, or an energy conversion module or the like. The chip 10 can be electrically connected to a prefabricated circuit board (for example, a printed circuit board) through a substrate, and the sensor module can be encapsulated by manufacturing a plastic packaging structure covering the sides of the sensor module to obtain a sensor.

Although implementations disclosed in the present application are as above, it should be noted that the above implementations are exemplary only rather than restrictive. Therefore, the present application is not limited to what is specifically shown and described herein. Various modifications, substitutions or omissions may be made in forms and details of implementations without departing from the scope of the present application.

1. A substrate comprising a base substrate configured to be connected with a chip, wherein the base substrate is provided with a plurality of through-holes which penetrate the base substrate in a direction perpendicular to the chip, stacked structures are sequentially provided within the through-holes in a direction perpendicular to and away from the base substrate, and thermal expansion coefficients of each layer in the stacked structures are different; and
the stacked structures include a first conductive portion electrically connected to the chip.

2. The substrate according to claim 1, wherein the stacked structures further comprise a cavity provided on a side of the first conductive portion away from the chip.

3. The substrate according to claim 2, wherein the substrate further comprises a second conductive portion which is provided on a side of the first conductive portion away from the chip and closes a side of a through-hole away from the chip, and the first conductive portion and the second conductive portion jointly enclose a chamber.

4. The substrate according to claim 3, wherein the second conductive portion is provided with a via which penetrates the second conductive portion in the direction perpendicular to the chip and communicates with the chamber; and
wherein a diameter of the via is 10 μm to 20 μm.

5. (canceled)

6. The substrate according to claim 1, wherein the stacked structures further comprise a buffer layer which is provided on a side of the base substrate away from the chip, and the first conductive portion is provided on a side of the buffer layer away from the chip; and
wherein a thermal expansion coefficient of a material of the buffer layer is between a thermal expansion coefficient of a material of the base substrate and a thermal expansion coefficient of a material of the first conductive portion.

7. (canceled)

8. The substrate according to claim 1, wherein the first conductive portion is provided with a groove.

9. The substrate according to claim 8, wherein at least one groove is provided within a through-hole.

10. The substrate according to claim 9, wherein a plurality of grooves are provided within the through-hole, and the plurality of grooves are uniformly distributed around an axis of the through-hole.

11. The substrate according to claim 8, wherein at least one groove is provided around the through-hole.

12. The substrate according to claim 11, wherein a plurality of grooves are provided around the through-hole, and the plurality of grooves are uniformly distributed around an axis of the through-hole.

13. The substrate according to claim 8, wherein an orthographic projection of the groove on the chip is circular, linear, or arc-shaped.

14. The substrate according to claim 1, wherein the stacked structures further comprise a filler which is provided on a side of the first conductive portion away from the chip and closes a side of a through-hole away from the chip; and
wherein a material of the filler has a negative thermal expansion coefficient.

15. (canceled)

16. A sensor module comprising:
the substrate according to claim 1; and
a chip, which is electrically connected to a surface of the base substrate close to the chip.

17. A manufacturing method of a substrate, comprising:
providing a base substrate connected to a chip;
forming a plurality of through-holes on the base substrate, the through-holes penetrating the base substrate in a direction perpendicular to the chip; and
forming stacked structures sequentially within the through-holes in a direction perpendicular to and away from the base substrate, wherein thermal expansion coefficients of each layer in the stacked structures are different, and the stacked structures include a first conductive portion electrically connected to the chip.

18. The manufacturing method of the substrate according to claim 17, further comprising forming a cavity on a side of the first conductive portion away from the chip.

19. The manufacturing method of the substrate according to claim 17, further comprising:
forming a second conductive portion on a side of the first conductive portion away from the chip, and closing a side of a through-hole away from the chip, wherein the first conductive portion and the second conductive portion jointly enclose a chamber.

20. The manufacturing method of the substrate according to claim 19, further comprising forming a via on the second conductive portion, the via penetrating the second conductive portion in the direction perpendicular to the chip and communicating with the chamber.

21. The manufacturing method of the substrate according to claim 19, wherein the first conductive portion is at least electroplated on a hole wall of the through-hole and on the chip exposed to the through-hole by a first electroplating current;
the second conductive portion is electroplated on the side of the first conductive portion away from the chip by a second electroplating current; and
the first electroplating current is less than the second electroplating current.

22. The manufacturing method of the substrate according to claim 17, wherein forming the stacked structures sequentially within the through-holes in the direction perpendicular to and away from the base substrate comprising,
forming a buffer layer on a side of the base substrate away from the chip; and
forming the first conductive portion on a side of the buffer layer away from the chip.

23. The manufacturing method of the substrate according to claim 17, further comprising forming a groove on the first conductive portion; or
further comprising forming a filler on a side of the first conductive portion away from the chip.

24. (canceled)
